(19) United States
(12) Patent Application Publication
(10) Pub. No.: US 2024/0055462 A1
(43) Pub. Date: Feb. 15, 2024

(54) IMAGE SENSOR DEVICE AND MANUFACTURING METHOD THEREOF

(71) Applicant: TAIWAN SEMICONDUCTOR MANUFACTURING COMPANY, LTD., Hsinchu (TW)

(72) Inventors: Yu-Wei HUANG, Tainan (TW); Chen-Hsien LIN, Tainan (TW); Tzu-Hsuan HSU, Kaohsiung (TW)

(21) Appl. No.: 17/887,983

(22) Filed: Aug. 15, 2022

(51) Int. Cl. H01L 27/146

(52) U.S. Cl. CPC H01L 27/1464; H01L 27/14621; H01L 27/14627; H01L 27/14636; H01L 27/14685; H01L 27/1463

(57) ABSTRACT

An image sensor device and methods of forming an image sensor device are provided. The image sensor device includes a plurality of image-sensing elements arranged within the device substrate. The image sensor device further includes an isolation grid structure extending into the device substrate and made up of a plurality of isolation grid segments that surround the outer perimeters of the plurality of image-sensing elements. The isolation grid structure includes a passivation liner and a conductive material in contact with the passivation liner. The conductive material may be an indium-tin-oxide film.

### BACKGROUND

Digital cameras and other optical imaging devices often employ optical structures such as semiconductor image sensors. Optical structures can be used to sense radiation and may convert optical images to digital data that may be represented as digital images. For example, complementary metal-oxide-semiconductor (CMOS) image sensors (CIS) and charge-coupled device (CCD) sensors are widely used in various applications such as digital cameras, mobile phones, detectors, or the like. The optical structures utilize light detection regions to sense light, wherein the light detection regions may include pixel arrays, illumination image sensors, or other types of image sensor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of an image sensor device including an isolation grid structure in accordance with some embodiments.

FIG. 1B illustrates an enlarged cross-sectional view of a portion of the image sensor device of FIG. 1A in accordance with some embodiments.

FIG. 1C is a schematic plan view of the image sensor device of FIG. 1A.

FIG. 2 illustrates a flow chart of a method for manufacturing an image sensor in accordance with some embodiments.

FIGS. 3-18, 19A-19C, 20A-20C, and 21A-21D illustrate views of various stages of manufacturing an image sensor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some variation of the example methods and structures are described. A person having ordinary skill in the art will readily understand other modifications that may be made that are contemplated within the scope of other embodiments. Although method embodiments may be described in a particular order, various other method embodiments may be performed in any logical order and may include fewer or more steps than what is described herein. In some figures, some reference numbers of components or features illustrated therein may be omitted to avoid obscuring other components or features; this is for ease of depicting the figures.

Light detection devices include frontside illumination (FSI) image sensor devices, backside illumination (BSI) image sensor devices, both having an array of pixel sensors, or other suitable image sensor device designs. One challenge of image sensor devices is crosstalk between adjacent light detection regions, or adjacent pixels. Optical crosstalk may occur when photons that are intended to be received by one light detection region, end up being erroneously received by a neighboring light detection region. Optical crosstalk may degrade the performance, for example, the resolution, of the image sensor device. As image sensor devices become smaller and smaller through development, the risk of crosstalk increases significantly.

Improvement in quantum efficiency (QE) is also a sought-after characteristic as image sensor devices develop. QE is a ratio of the number of photons that contribute to an electrical signal generated by an image-sensing element within a pixel region to the number of photons incident on the pixel region. Incident light may not penetrate through metallic materials, or metallic material is opaque to photons. When metallic structures are present in an image sensor device, photons impinging on the metallic structures may not contribute to electrons generated, and therefore the QE of the image sensor may be reduced.

Image sensor devices may also suffer from dark current. Dark current is unwanted current generated by pixels in the absence of illumination. There can be different sources of dark current including, for example, impurities in silicon, damage to the silicon crystal lattice during processing, and heat build-up in the pixel area. Excessive dark current may lead to image degradation and poor device performance. Image sensor devices with high QEs, low crosstalk, and low dark current are highly desirable.

Some image sensor devices utilize deep trench isolation (DTI) structures to isolate neighboring active regions, for example, pixel regions from one another. These DTI structures are often filled with oxides and conductive metals. However, these DTI structures often suffer from QE degradation and voltage bias insufficiency due to the thickness of the oxide used in these DTI structures.

Various embodiments provide an image sensor device with a DTI structure including a conductive oxide film and methods of forming the image sensor device. In some embodiments, the conductive oxide film is directly formed on a passivation liner of the DTI structure. The conductive oxide film may be selected from a material that is electrically conductive and with a refractive index (n) similar to silicon oxide. The conductive oxide file may be selected from various transparent conductive oxides (TCOs). In some embodiments, the transparent conductive oxide film includes an indium tin oxide film.

In some embodiments, the DTI structure including the conductive oxide film achieves a conductible DTI for efficient voltage biasing while enabling incident light total reflection without QE degradation. The passivation film in the DTI structure can be biased via the conductive oxide film to reduce crosstalk. Thus, the DTI structure including the conductive oxide film reduces crosstalk and improves QE of the resultant image-sensing device. The DTI structure including the conductive oxide film can be easily embedded and/or positioned within different image-sensing devices based upon the optical needs of the user. The DTI structure including the conductive oxide film can be formed using thin film techniques. In addition, the DTI structure including the conductive oxide film can be used in conjunction with currently available grid structures to further reduce crosstalk without sacrificing QE while also improving dark performance.

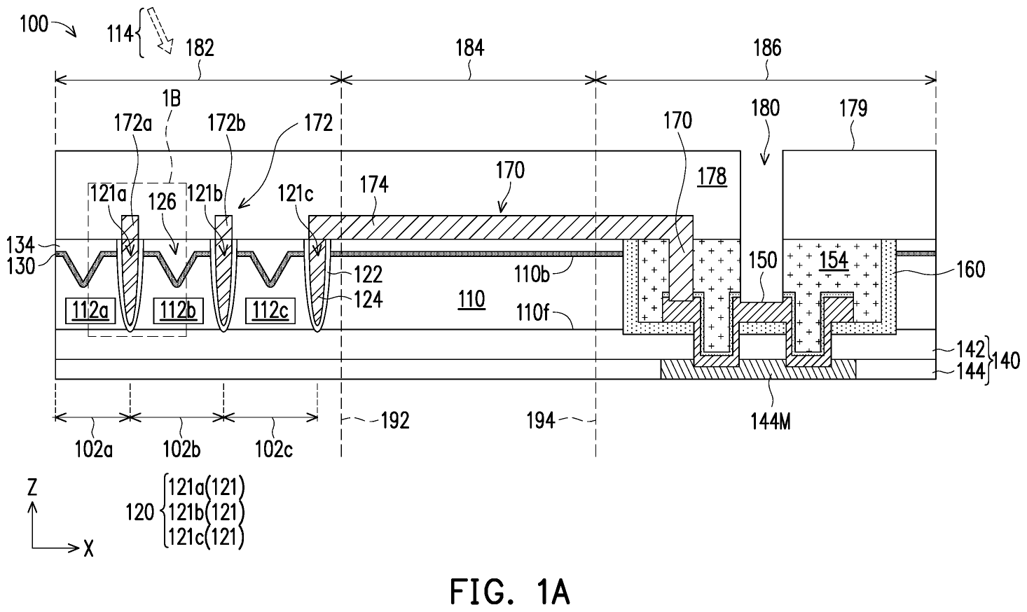

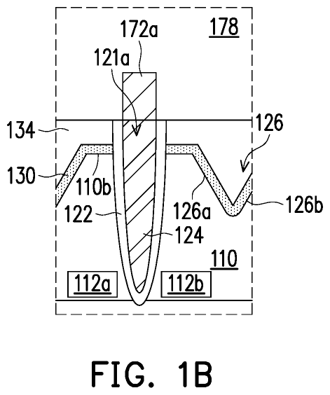

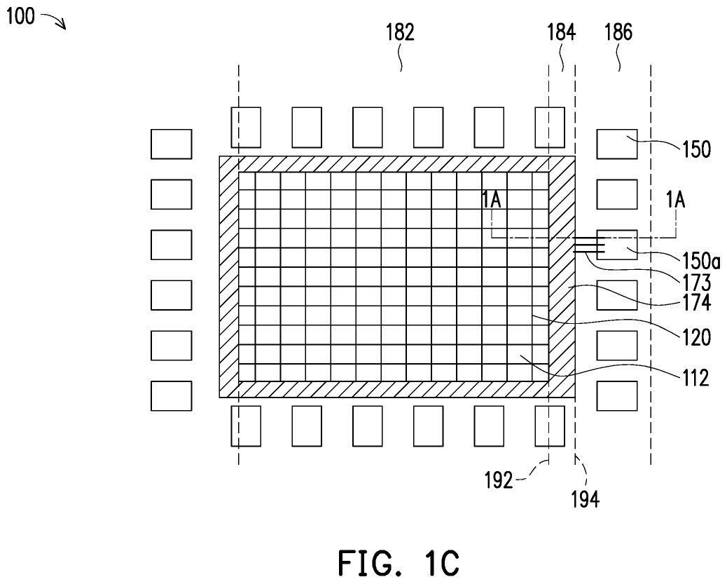

FIG. 1A illustrates an image sensor device 100 including an isolation grid structure 120 including a conductive oxide film in accordance with some embodiments. FIG. 1B illustrates an enlarged cross-sectional view of a portion of the image sensor device 100 of FIG. 1A in accordance with some embodiments. FIG. 1C is a schematic plan view of the image sensor device of FIG. 1A. Particularly, FIG. 1A is a schematic cross-sectional view of the image sensor device 100 across a line 1A-1A in FIG. 1C.

The image sensor device 100 at least includes a device substrate 110, one or more image-sensing elements 112a-c formed in the device substrate 110, and the isolation grid structure 120 having a conductive oxide film formed therein. The image sensor device 100 may further include a conductive bonding pad structure 150, a bias pad structure 170 including a light blocking grid section 172 and a bias pad layer 174, micro-lenses, and/or color filters.

The image sensor device 100 includes the device substrate 110. In some embodiments, the device substrate 110 is a p-type semiconductor substrate (P-Substrate) or an n-type semiconductor substrate (N-Substrate) comprising silicon. In some other alternative embodiments, the device substrate 110 includes other elementary semiconductor materials, such as germanium; a compound semiconductor including silicon carbide, gallium arsenic, gallium phosphide, indium phosphide, indium arsenide, and/or indium antimonide; an alloy semiconductor including silicon germanium (SiGe), gallium arsenide phosphide (GaAsP), aluminum indium arsenide (AlInAs), aluminum gallium arsenide (AlGaAs), indium gallium arsenide (InGaAs), indium gallium phosphide (InGaP), indium gallium arsenide phosphide (InGaAsP), combinations thereof, or the like. In some other embodiments, the device substrate 110 is a semiconductor on insulator (SOI). In some other embodiments, the device substrate 110 may include an epitaxial layer, a gradient semiconductor layer, and/or a semiconductor layer overlying another different type of semiconductor layer, such as a silicon layer on a silicon germanium layer. The device substrate 110 may or may not include doped regions, such as a p-well, an n-well, or combination thereof.

The device substrate 110 has a frontside 110f (also referred to as a front surface) and a backside 110b (also referred to as a back surface) opposite the frontside 110f. The device substrate 110 includes, for example, image-sensing elements 112a, 112b, and 112c (collectively 112), arranged to correspond to a light detection region 102a-c, respectively. The image-sensing elements 112a-c are configured to sense radiation (or radiation waves), such as an incident radiation 114, that is projected toward the device substrate 110 from the backside 110b. The incident radiation 114 would enter the device substrate 110 through the backside 110b (or the back surface) and be detected by one or more of the image-sensing elements 112a-c. The image-sensing elements 112a-c can be arranged in rows and/or columns within the device substrate 110. In some embodiments, each light detection region 102a-c includes image-sensing elements arranged in an array including one or more rows or and one or more columns. For example, the light detection region 102a-c may include two columns and two rows (e.g., a 2×2 structure). It will be appreciated that the light detection region 102a-c may include other combinations of rows and columns, for example, one row and two columns (e.g., a 2×1 structure) or one row and one column (e.g., a 1×1 structure). In some embodiments, the image-sensing elements 112a-c each include a photodiode. In other embodiments, the image-sensing elements 112a-c may include pinned layer photodiodes, photogates, reset transistors, source follower transistors, and/or transfer transistors. The image-sensing elements 112a-c may also be referred to as radiation-detection devices or pixel sensors.

In some embodiments, the image sensor device 100 may further include an isolation grid structure 120 formed in the device substrate 110. The isolation grid structure 120 includes isolation grid segments 121a, 121b, and 121c (collectively 121). In some embodiments, the isolation grid structure 120 may be a DTI structure, such as a backside deep trench isolation (BDTI) structure. The isolation grid structure 120 defines a substrate isolation grid, made up of grid segments, such as individual rectangles, squares, or other shapes which abut one another. Further, in some embodiments, the isolation grid structure 120 extends into the device substrate 110 from either above or about even with the backside 110b of the device substrate 110. The isolation grid structure 120 is laterally arranged around and between the image-sensing elements 112a-c to advantageously provide optical isolation between neighboring image-sensing elements 112a-c. The isolation grid structure 120 can include an isolation material selected from a high-k dielectric material, a transparent conducting oxide, a dielectric material, a low-n material, a metallic material, or a multi-layer combination thereof. In some embodiments, the isolation grid structure 120 includes a passivation liner 122 and a conductive material 124. The conductive material 124 may include a transparent conductive oxide, for example, a conductive oxide film with a refractive index (n) comparable to silicon oxide. In some embodiments, the conductive material 124 has a refractive index (n) in a range from about 1.35 to about 1.8. In some embodiments, the conductive material 124 may a transparent conductive oxide film. In some embodiments, the transparent conductive oxide film includes a mixture of group III metal oxide and group IV metal oxide, for example a mixture of indium(III) oxide (In₂O₃) and tin(IV) oxide (SnO₂), or an ITO film. In some embodiments, the passivation liner 122 has a refractive index (n) in a range from about 1.6 to about 2.1. Further, in some embodiments, the passivation liner 122 is a high-k dielectric, such as an aluminum oxide (e.g., AIxOy), hafnium oxide (e.g., HfO₂), or a material with a refractive index less than silicon.

In some embodiments, the backside 110b of the device substrate 110 is planar. In other embodiments, as shown in FIGS. 1A and 1B, the backside 110b of the device substrate 110 is characterized by a non-planar surface defining a plurality of topographical features 126 arranged in a periodic pattern within the plurality of light detection regions 102a-c. Referring to FIG. 1B, the plurality of topographical features 126 (e.g., inverted pyramidal shaped depressions and/or protrusions) are defined by a plurality of interior surfaces 126a-b of the device substrate 110. The plurality of interior surfaces 126a-b can include substantially flat or flat surfaces that respectively extend along planes extending in a first direction and in a second direction (e.g., into the plane of the paper) that is perpendicular to the first direction. The flatness of the plurality of interior surfaces 126a-b is a result of a wet etching process used to form the topographical features 126. The individual depressions may have sidewalls configured to comprise cone shapes having a peak or may have substantially planar triangularly shaped sidewalls configured to form a peak and collectively to form pyramidal structures or may have other easily produced shapes using semiconductor fabrication techniques. For example, the sides of the pyramidal shapes may be substantially planar, convex, or concave. In some embodiments, the plurality of topographical features 126 provide QE enhancement for image sensor devices used in near-infrared (NIR) applications.

In some embodiments, a passivation layer 130 is arranged over the backside 110b of the device substrate 110. In some embodiments where the topographical features 126 are present, the passivation layer 130 may be formed between the plurality of interior surfaces 126a-b. In some embodiments, the passivation layer is arranged between the backside 110b of the device substrate 110 and a light transmission layer 134. In some embodiments, the passivation layer 130 is a conformal layer. In some embodiments, the passivation layer 130 may include a high-k dielectric material such as titanium aluminum oxide, hafnium tantalum oxide, zirconium lanthanum oxide, or the like. The light transmission layer 134 includes a backside 134b, a frontside 134f opposite the backside 134b, the frontside 134f of the light transmission layer 134 is adjacent to the backside 110b of the device substrate 110. The light transmission layer 134 may include an oxide, a nitride, a carbide, or the like. The light transmission layer 134 may fill the depressions defined by the interior surfaces 126a-b and extend along the backside 110b of the device substrate 110 in a black level correction (BLC) region 184. The light transmission layer 134 may extend above the backside 110b of the device substrate to a thickness in a range from about 100 Å to about 1500 Å. The angles of the plurality of interior surfaces 126a-b may increase absorption of radiation by the device substrate 110 (e.g., by reducing a reflection of radiation from the uneven surface). For example, for incident radiation 114 (e.g., incident radiation having a wavelength that is in a near infrared portion of the electromagnetic spectrum) having an angle of incidence greater than a critical angle, one of the plurality of interior surfaces 126a-b may act to reflect the incident radiation 114 to another one of the plurality of interior surfaces 126a-b, where the incident radiation 114 can be subsequently absorbed into the device substrate 110. The plurality of interior surfaces 126a-b may further act to reduce an angle of incidence for incident radiation 114 having a steep angle with respect to the backside 134b of the light transmission layer 134, thereby preventing the incident radiation 114 from reflecting from the device substrate 110.

The image-sensing elements 112a-c, for example, photodetectors, are formed in a region of the image sensor device 100 referred to as a pixel array region 182 (or a pixel-array region). The image sensor device 100 may further include the BLC region 184 laterally surrounding the pixel array region 182. In addition, the image sensor device 100 may further include a bonding pad region 186. The dashed line 192 and the dashed line 194 in FIGS. 1A and 1C designate approximate boundaries between the regions 182, 184, and 186, though it is understood that the regions 182, 184, and 186 are not drawn to scale herein and may extend vertically above and below the image sensor device 100.

The isolation grid structure 120 may be used in the pixel array region 182 of the image sensor device 100 depicted in FIGS. 1A and 1C. The isolation grid structure 120 may be used in optical devices other than the image sensor device 100 of FIG. 1A.

The BLC region 184 typically includes devices that are kept optically dark. For example, the BLC region 184 may include a digital device, such as an application-specific integrated circuit (ASIC) device, a system-on-chip (SOC) device, and/or a logic circuit. In some embodiments, the BLC region 184 includes a reference pixel (not shown) that is used to establish a baseline of an intensity of light for the image sensor device 100.

The bonding pad region 186 includes a region where one or more conductive bonding pad structures 150 of the image sensor device 100 are formed so that electrical connections between the image sensor device 100 and external devices may be established. Among other things, the bonding pad region 186 may contain an isolation structure, such as a shallow trench isolation (STI) to help insulate the silicon of the device substrate 110 from the one or more conductive bonding pad structures 150 formed in the bonding pad region 186.

Although not illustrated herein for reasons of simplicity, it is understood that the image sensor device 100 may also include additional regions, for example, a buffer region, and/or a scribe line region. The scribe line region includes a region that separates one semiconductor die (for example, a semiconductor die that includes the bonding pad region 186, the BLC region 184, and the pixel array region 182 from an adjacent semiconductor die (not illustrated)). The scribe line region is cut therethrough in a later fabrication process to separate adjacent dies before the dies are packaged and sold as integrated circuit chips. The scribe line region is cut in such a way that the semiconductor devices in each die are not damaged.

In some embodiments, the image sensor device 100 further includes an interconnect structure 140 formed over the frontside 110f of the device substrate 110, thereby forming electrical circuits with the image-sensing elements 112a-c. The interconnect structure 140 may include an ILD layer 142 and/or IMD layers 144 containing conductive features (e.g., conductive lines and vias comprising copper, aluminum, tungsten, combinations thereof, and the like) formed using any suitable method, such as damascene, dual damascene, or the like. For example, the interconnect structure 140 may include a conductive line 144M as shown in FIG. 1A. In some embodiments, as shown in FIG. 1A, the conductive line 144M is formed in the bonding pad region 186. The ILD layer 142 and IMD layer 144 may include low-k dielectric materials having k-values, for example, lower than about 4.0 or even 2.0 disposed between such conductive features. In some embodiments, the ILD layer 142 and the IMD layer 144 may be made of, for example, phosphosilicate glass (PSG), borophosphosilicate glass (BPSG), fluorosilicate glass (FSG), SiOₓC_{y}, Spin-On-Glass, Spin-On-Polymers, silicon carbon material, compounds thereof, composites thereof, combinations thereof, or the like, formed by any suitable method, such as spin-on techniques, chemical vapor deposition (CVD), plasma-enhanced CVD (PECVD), or the like.

In some embodiments, the conductive bonding pad structure 150 is formed on the exposed surface of the conductive line 144M in the bonding pad region 186. The conductive bonding pad structure 150 may be formed by one or more deposition and patterning processes. In some embodiments, the conductive bonding pad structure 150 contains aluminum. In other embodiments, the conductive bonding pad structure 150 may contain another suitable metal, for example copper. A bonding wire (or another electrical interconnection element) may be attached to the conductive bonding pad structure 150 in a later process, and accordingly the conductive bonding pad structure 150 may also be referred to as a bond pad or a conductive pad. Also, since the conductive bonding pad structure 150 is formed on the conductive line 144M, it is electrically coupled to the conductive line 144M and the rest of the interconnect structure 140 through the conductive line 144M. In other words, electrical connections may be established between external devices and the image sensor device 100 at least in part through the conductive bonding pad structure 150.

In some embodiments, the image sensor device 100 further includes a dielectric fill material 154. The dielectric fill material 154 is formed to cover the conductive bonding pad structure 150 and to subsequently fill any peripheral openings. The dielectric fill material 154 is used to protect the conductive bonding pad structure 150 during subsequent processing steps and can be deposited by a blanket deposition process followed by a planarization process such that a top surface of the dielectric fill material 154 is planar or substantially planar.

In some embodiments, the image sensor device 100 further includes a buffer oxide layer 160. The buffer oxide layer 160 may be formed in between the interconnect structure 140 and the conductive bonding pad structure 150. The buffer oxide layer 160 separates the conductive bonding pad structure 150 from the device substrate 110 while allowing the conductive bonding pad structure 150 to contact the conductive line 144M.

In some embodiments, the image sensor device 100 further includes the bias pad structure 170. The bias pad structure 170 is composed of a reflective metal material, for example, copper, gold, silver, aluminum, nickel, tungsten, alloys thereof, or the like. The bias pad structure 170 includes a light blocking grid section 172 in the pixel array region 182 and a bias pad layer 174 in the BLC region 184. The light blocking grid section 172 may prevent optical crosstalk between adjacent image-sensing elements 112a-c. The bias pad layer 174 may cover any reference pixels present in the BLC region 184. For example, the bias pad layer 174 may cover the entirety of the backside 134b of the light transmission layer 134 in the BLC region. In addition, the bias pad layer 174 may electrically couple the isolation grid structure 120 with the conductive bonding pad structure 150 such that the isolation structure can be biased using one or more of the conductive bonding pad structure 150, as shown in FIG. 1C. For example, as shown in FIGS. 1A and 1C, the bias pad layer 174 electrically couples the conductive bonding pad structure 150 via conductive lines 173, and the bias pad layer 174 is electrically coupled with isolation grid segment 121c, which also allows biasing of isolation grid segments 121a and 121b, and light blocking grid segments 172a-b of the light blocking grid section 172 positioned over the isolation grid segments 121a and 121b, respectively.

Still referring to FIG. 1A, in some embodiments, a dielectric layer 178 is formed over the backside 110b of the device substrate 110. In some embodiments, the dielectric layer 178 includes a dielectric material, for example, an oxide such as silicon oxide (SiO2) although other suitable dielectric materials may be used. Alternatively, the dielectric layer 178 may include a nitride, for example, silicon nitride (SiN). The dielectric layer 178 may be formed by chemical vapor deposition (CVD), physical vapor deposition (PVD), or other suitable techniques. In some embodiments, the dielectric layer 178 is planarized to form a smooth surface by a chemical mechanical planarization (CMP) process. Among other things, the dielectric layer 178 provides mechanical strength and support during additional processing of the device substrate 110.

An opening 180 is formed in the bonding pad region 186. The opening 180 extends from a top surface 179 of the dielectric layer 178 toward the conductive bonding pad structure 150 exposing the conductive bonding pad structure 150. An etching process may be performed to remove a portion of the dielectric layer 178 and a portion of the dielectric fill material 154 in the bonding pad region 186 thereby forming the opening 180 in the bonding pad region 186.

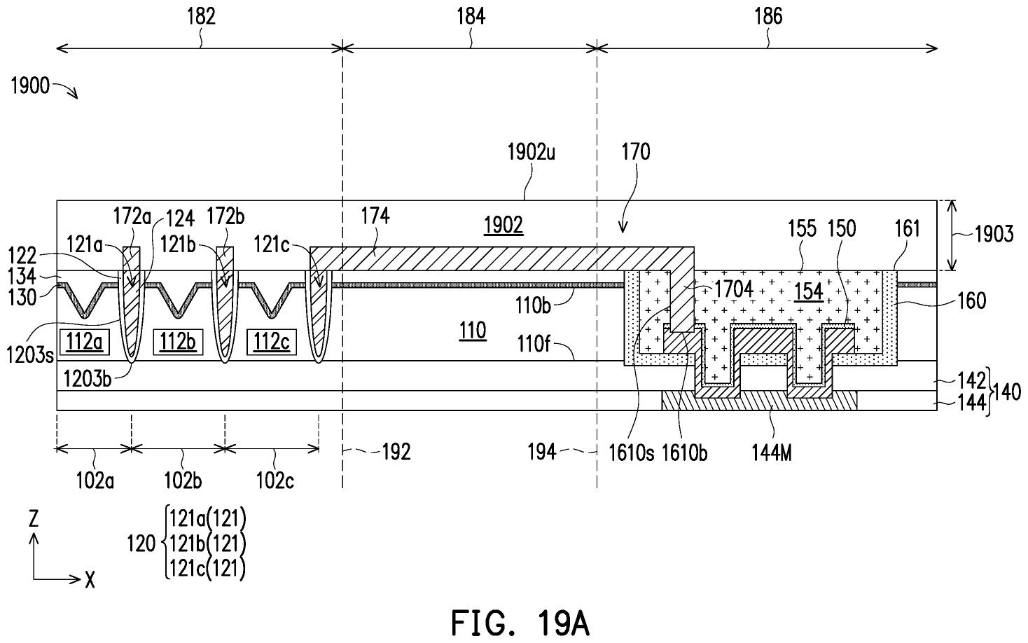

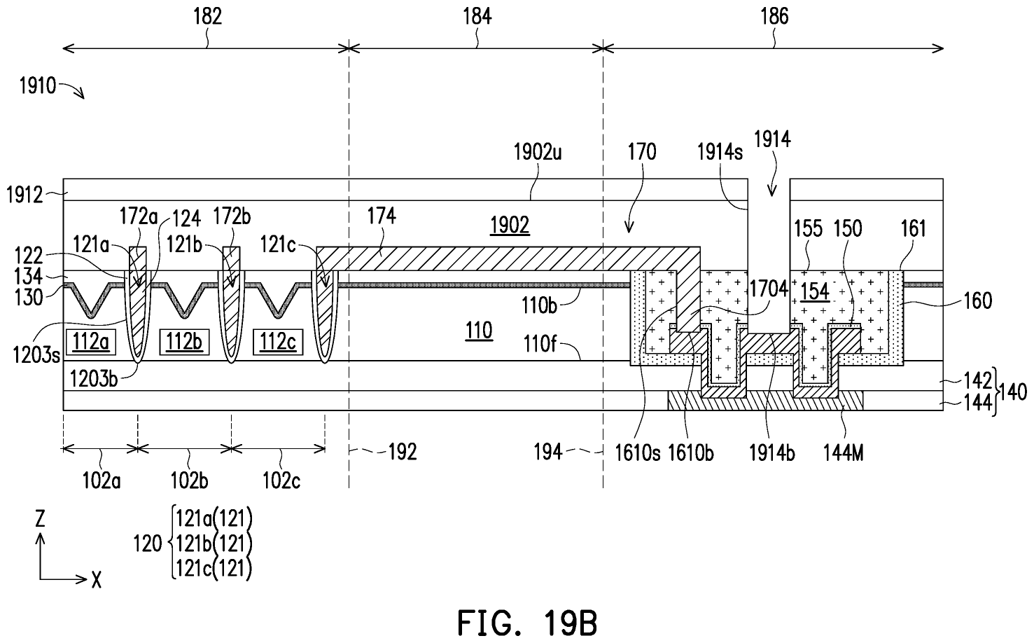

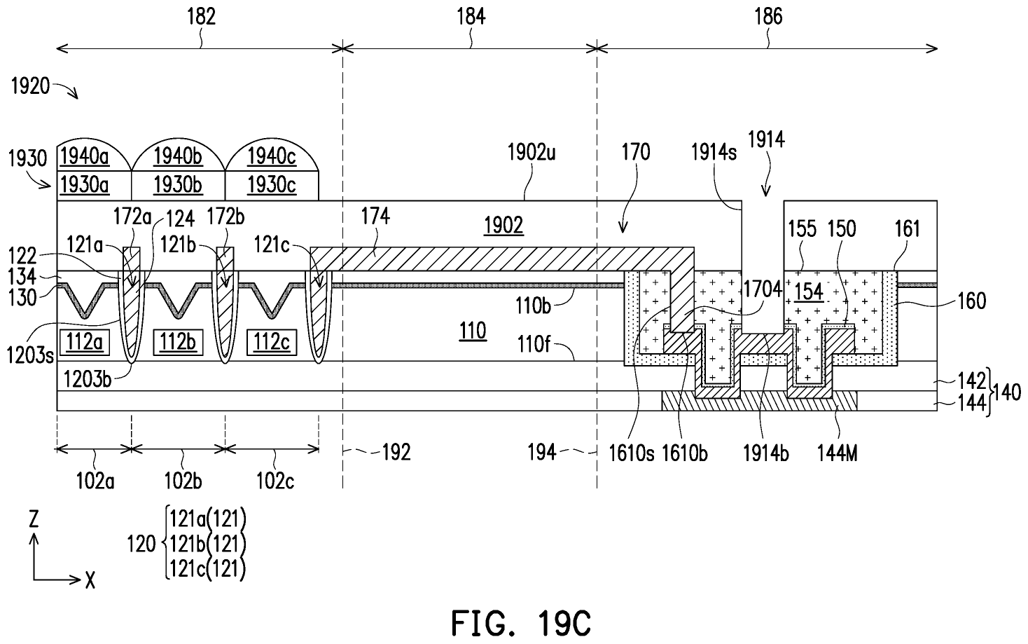

The image sensor device 100 may further include color filters and micro-lenses as will be described herein, for example, in FIGS. 19C, 20C, and 21D.

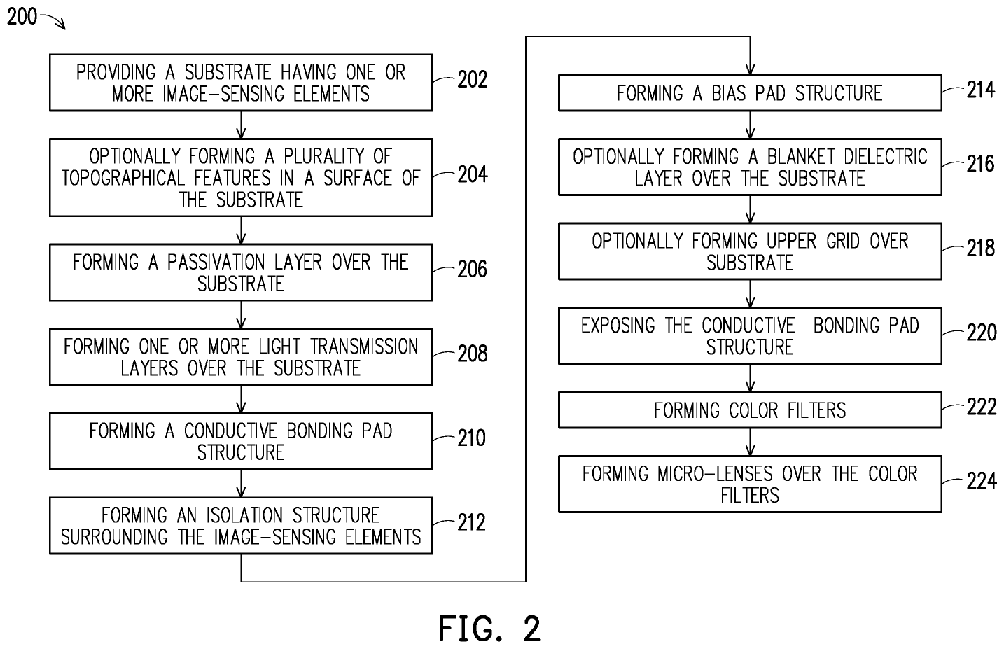

FIG. 2 illustrates a flow chart of a method 200 for manufacturing an image sensor device in accordance with some embodiments. The method 200 may be used to form the image sensor device 100. The method 200 may be used to form other image sensor devices.

At operation 202, a substrate is provided. The substrate may be a device substrate or semiconductor substrate as described herein. The substrate may have image-sensing elements and/or pixels already formed therein.

Optionally, at operation 204, a plurality of topographical features may be formed in a surface of the substrate. The plurality of topographical feature may be formed in the backside surface of the substrate.

At operation 206, a passivation layer may be formed over the substrate. If the plurality of topographical features is present, the passivation layer may be formed over the plurality of feature formed in the backside surface of the substrate.

At operation 208, a light transmission layer may be formed over the substrate. If the passivation layer is present, the light transmission layer may be formed over the passivation layer formed along the backside surface of the substrate.

At operation 210, one or more conductive bonding pad structures may be formed.

At operation 212, an isolation structure surrounding the image-sensing elements may be formed. The isolation structure may be a DTI structure, such as a BDTI structure. The isolation structure may define a substrate isolation grid, made up of grid segments, such as individual rectangles, squares, or other shapes which abut one another. The isolation structure includes a conductive oxide film. The isolation structure may further include a passivation liner.

At operation 214, a bias pad structure is formed over the substrate. The bias pad structure may include a bias pad layer and a light blocking grid. The light blocking grid may be formed over the isolation structure. The light blocking grid may define openings within which the color filters are arranged.

At operation 216, optionally, a blanket dielectric layer may be formed over the substrate. If the light blocking grid is present, the blanket dielectric layer may fill the openings defined by the light blocking grid.

At operation 218, an upper grid may be formed over the substrate. If the light blocking grid is present the upper grid may be formed over the light blocking grid such that the openings defined by the light blocking grid are aligned with the openings defined by the upper grid.

At operation 220, the conductive bonding pad may be exposed.

At operation 222, color filters are formed in the openings defined by the upper grid structure.

At operation 224, micro lenses are formed over the color filters.

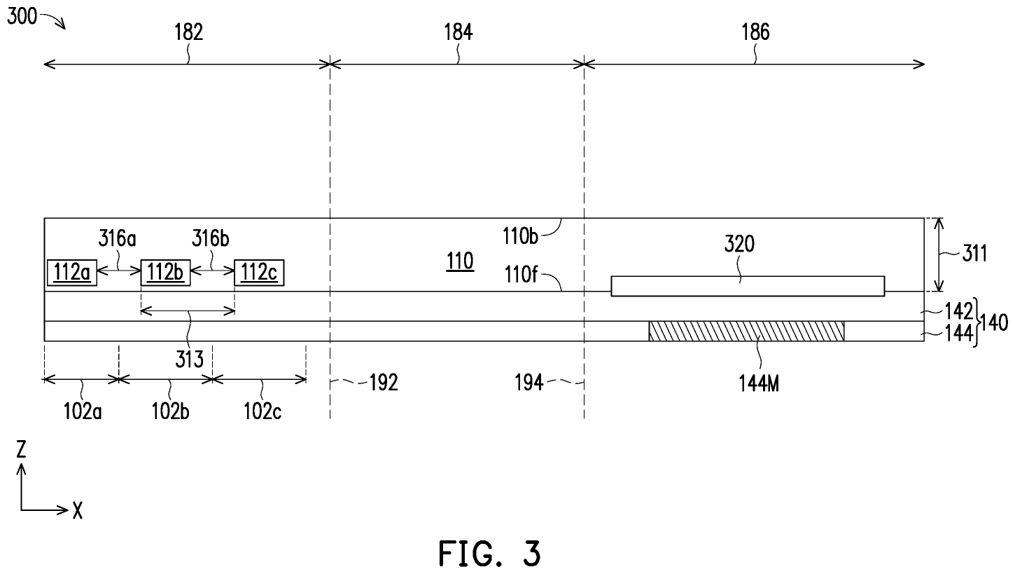

With reference to FIGS. 3-18, 19A-19C, 20A-20C, and 21A-21D, cross-sectional views of some embodiments of a device structure for image sensors at various stages of manufacture are provided to illustrate the method of FIG. 2. Although FIGS. 3-18, 19A-19C, 20A-20C, and 21A-21D are described in relation to the method 200, it will be appreciated that the structures disclosed in FIGS. 3-18, 19A-19C, 20A-20C, and 21A-21D are not limited to the method 200, but instead may stand alone as structures independent of the method 200. Similarly, although the method 200 is described in relation to FIGS. 3-18, 19A-19C, 20A-20C, and 21A-21D, it will be appreciated that the method 200 is not limited to the structures disclosed in FIGS. 3-18, 19A-19C, 20A-20C, and 21A-21D, but instead may stand alone independent of the structures disclosed in FIGS. 3-18, 19A-19C, 20A-20C, and 21A-21D.

FIGS. 3-18, 19A-19C, 20A-20C, and 21A-21D illustrate cross-sectional side views of various stages of manufacturing an image sensor device 100 including an isolation grid structure 120 having a conductive oxide film in accordance with some embodiments.

FIG. 3 illustrates a cross-sectional view 300 of an image sensor device during intermediate stages of manufacturing operations corresponding to operation 202, in accordance with some embodiments. The device substrate 110 has the frontside 110f and the backside 110b opposite the frontside 110f. In some embodiments, as depicted in FIG. 3, the device substrate 110 has an initial thickness 311 that is in a range from about 1 micron (μm) to about 10 μm. In particular embodiments, the initial thickness 311 of the device substrate 110 is in a range from about 2 μm to about 7 μm.

The device substrate 110 includes, for example, the image-sensing elements 112a-c, arranged to correspond to the light detection region 102a-c, respectively. The image-sensing elements 112a-c may be varied from one another to have different junction depths, thicknesses, widths, and so forth. For the sake of simplicity, only three image-sensing elements 112a-c are illustrated in FIG. 3, but it is understood that any number of image-sensing elements may be implemented in the device substrate 110. The image-sensing elements 112a-c may be formed by any suitable method. In some embodiments, the image-sensing elements 112a-c are formed by performing an implantation process on the device substrate 110 from the frontside 110f. The implantation process may include doping the device substrate 110 with a p-type dopant such as boron. In an alternative embodiment, the implantation process may include doping the device substrate 110 with an n-type dopant such as phosphorus or arsenic. In other embodiments, the image-sensing elements 112a-c may also be formed by a diffusion process.

The image-sensing elements 112a-c are separated from one another by a plurality of gaps in the device substrate 110. For example, a gap 316a separates the image-sensing elements 112a and 112b, a gap 316b separates the image-sensing elements 112b and 112c, and a gap (not illustrated) separates the image-sensing element 112a from an adjacent pixel to its left (not illustrated) if present. Of course, it is understood that the gaps 316a-b are not voids or open spaces in the device substrate 110, but they may be regions of the device substrate 110 (either a semiconductor material or a dielectric isolation element) that are located between the adjacent image-sensing elements 112a-c. In some embodiments, a distance 313 between adjacent image-sensing elements 112a-c or “pixel pitch” is single digit or sub-micron (e.g., less than 0.75 micrometers).

In some embodiments, a shallow trench isolation (STI) layer 320 may be formed at the frontside 110f of the device substrate 110 in the bonding pad region 186. The STI layer 320 may be formed by patterning the frontside 110f of the device substrate 110 to form a trench in the device substrate 110 and filling the trench with suitable dielectric materials to form the STI layer 320. The dielectric materials may include silicon oxides.

In some embodiments, an interconnect structure 140 is formed over the frontside 110f of the device substrate 110, thereby forming electrical circuits with the image-sensing elements 112a-c. The interconnect structure 140 may include an ILD layer 142 and/or IMD layers 144 containing conductive features (e.g., conductive lines and vias comprising copper, aluminum, tungsten, combinations thereof, and the like) formed using any suitable method, such as damascene, dual damascene, or the like. For example, the interconnect structure 140 may include a conductive line 144M as shown in FIG. 3. In some embodiments, as shown in FIG. 3, the conductive line 144M is formed in the bonding pad region 186. The ILD layer 142 and IMD layer 144 may include low-k dielectric materials having k-values, for example, lower than about 4.0 or even 2.0 disposed between such conductive features. In some embodiments, the ILD layer 142 and IMD layer 144 may be made of, for example, phosphosilicate glass (PSG), borophosphosilicate glass (BPSG), fluorosilicate glass (FSG), SiOₓC_{y}, Spin-On-Glass, Spin-On-Polymers, silicon carbon material, compounds thereof, composites thereof, combinations thereof, or the like. The ILD layer 142 and the IMD layer 144 may be formed by any suitable method, such as spin-on techniques, chemical vapor deposition (CVD), plasma-enhanced CVD (PECVD), or the like.

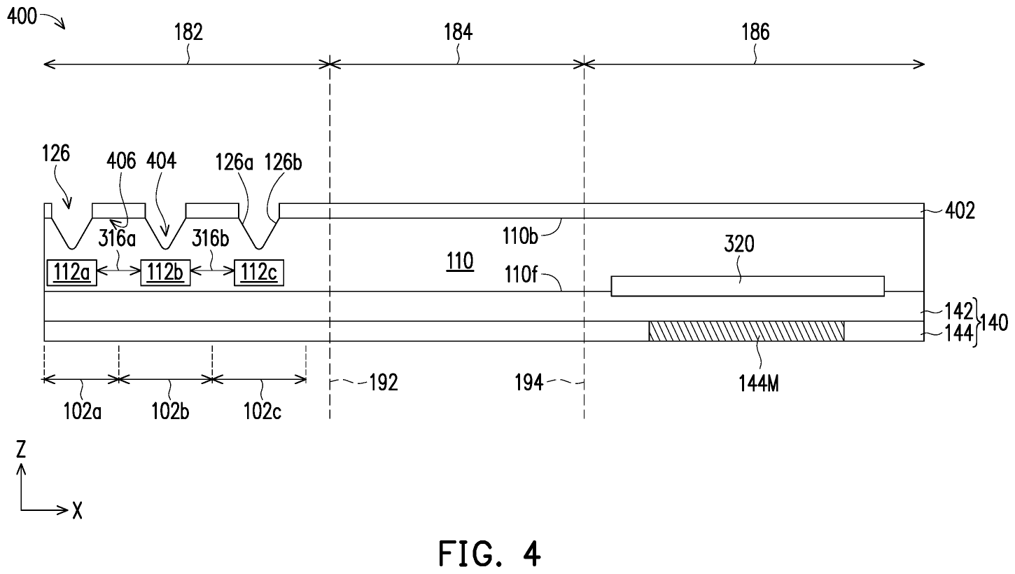

FIG. 4 illustrates a cross-sectional view 400 of an image sensor device during intermediate stages of manufacturing operations corresponding to operation 204, in accordance with some embodiments. Optionally, at operation 204, a plurality of topographical features, for example, the topographical features 126, may be formed in a surface of a substrate, for example, the backside 110b of the device substrate 110. As shown in cross-sectional view 400 of FIG. 4, a first etching process is performed on the backside 110b of the device substrate 110 according to the first patterned masking layer 402 of FIG. 4. The first etching process is performed by exposing the device substrate 110 to one or more etchants with the first patterned masking layer 402 in place. The one or more etchants remove parts of the device substrate 110 to define a plurality of recesses 404 arranged between a plurality of protrusions 406 or “mesas” extending outward from the device substrate 110. In some embodiments, as shown in FIG. 4, the plurality of protrusions 406 are flat protrusions having a flat top surface defined by the backside 110b of the device substrate 110. The plurality of protrusions 406 and the plurality of recesses 404 define the topographical features 126. The plurality of protrusions 406 and plurality of recesses 404 are coupled together by the interior surfaces 126a, 126b. In some embodiments, the plurality of interior surfaces 126a-b include substantially flat or flat surfaces that respectively extend along planes extending in a first direction and in a second direction (e.g., into the plane of the paper) that is perpendicular to the first direction. The flatness of the plurality of interior surfaces 126a-b is a result of a wet etching process used to form the topographical features 126. The plurality of protrusions 406 form a repeating periodic pattern of shapes of individual protrusions 406, and have an outer border confined within the projected area of the pixel array region 182. For example, as shown in FIG. 4, the plurality of topographical features 126 are arranged in a periodic pattern defined by each of the plurality of light detection regions 102a-c. In some embodiments, the first etching process may comprise a dry etching process. For example, the first etching process may comprise a coupled plasma etching process, such as an inductively coupled plasma (ICP) etching process or a capacitively coupled plasma (CCP) etching process. In other embodiments, the first etching process may comprise a wet etching process. In some embodiments, the wet etching process may include one or more wet etchants such as hydrofluoric acid (HF), tetramethylammonium hydroxide (TMAH), potassium hydroxide (KOH), or the like. After the first etching process, the first patterned masking layer 402 may be removed.

Although the topographical features 126 depicted in FIG. 4 have an inverted pyramid shape, it should be understood that other shapes may be used depending upon desired optical conditions. In some embodiments, the topographical features 126 may have sidewalls configured to include cone shapes having a peak or may have substantially planar triangularly shaped sidewalls configured to form a peak and collectively to form pyramidal structures or may have other easily produced shapes using semiconductor fabrication techniques. For example, the sides of the pyramidal shapes may be substantially planar, convex, or concave. In some embodiments, the plurality of topographical features 126 provide improved QE by reflecting light back toward the image sensor device that may normally become incident on an adjacent sensor absent the plurality of topographical features 126. Thus, crosstalk may be reduced, and QE may be increased.

In other embodiments where the backside 110b of the device substrate 110 is not patterned such that the backside 110b remains planar, operation 204 is skipped and the method 200 proceeds from operation 202 to operation 206.

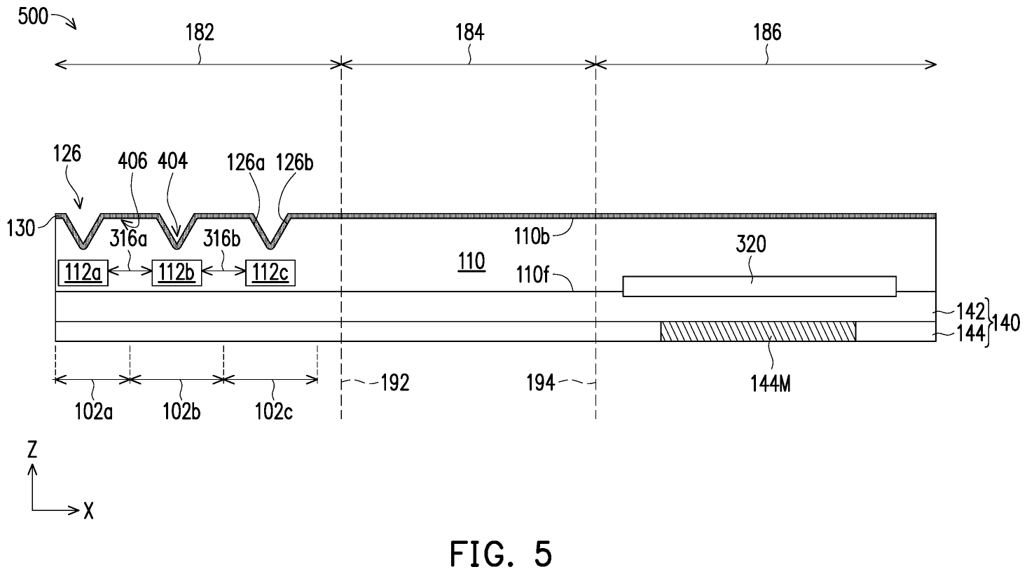

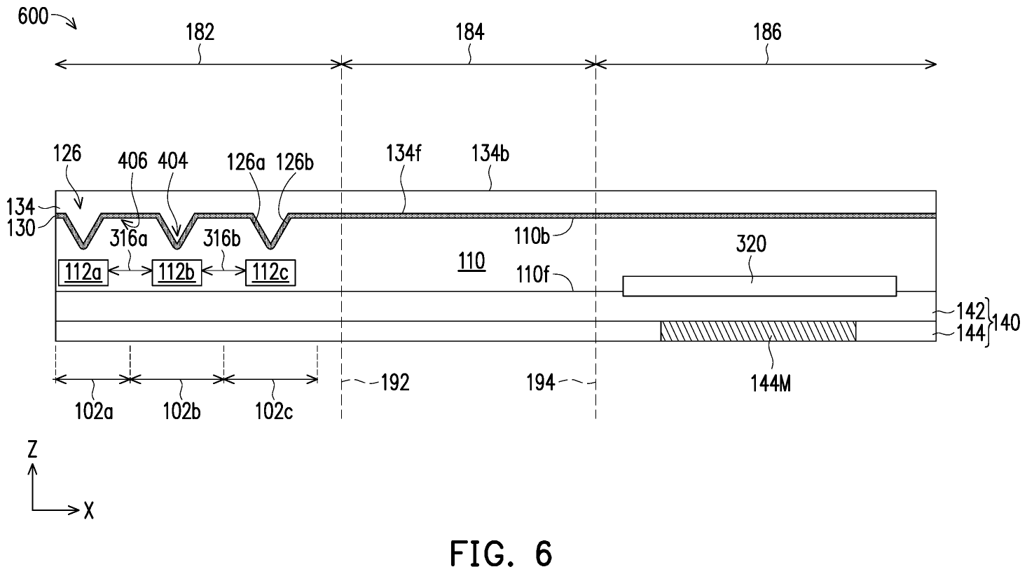

FIG. 5 illustrates a cross-sectional view 500 of an image sensor device during intermediate stages of manufacturing operations corresponding to operation 206, in accordance with some embodiments. Optionally, at operation 206, a passivation layer, for example, the passivation layer 130, may be formed over a surface of a substrate, for example, the backside 110b of the device substrate 110. The passivation layer 130 may separate the device substrate 110 from subsequently deposited layers, for example, the light transmission layer 134 (see FIG. 6). In addition, the passivation layer 130 may help alleviate crosstalk between adjacent light detection regions 102a-c. In some embodiments, as shown in FIG. 5, the passivation layer 130 is arranged over the backside 110b of the device substrate 110. In some embodiments where the topographical features 126 are present, the passivation layer 130 may be formed between the plurality of interior surfaces 126a-b. In some embodiments, the passivation layer 130 is arranged between the backside 110b of the device substrate 110 and the frontside 134f of the light transmission layer 134. In some embodiments, the passivation layer 130 is a conformal layer. In some embodiments, the passivation layer 130 includes a high-k dielectric material, a dielectric material, or a multilayer combination thereof. In some embodiments, the passivation layer 130 may include a high-k dielectric material such as aluminum oxide, tantalum oxide, hafnium oxide, hafnium silicon oxide, hafnium aluminum oxide, hafnium tantalum oxide, titanium aluminum oxide, zirconium lanthanum oxide, or the like. The passivation layer 130 may be deposited by any suitable process, for example, the passivation layer 130 may be deposited by vapor deposition, such as CVD, PVD, PECVD, ALD, or grown by thermal oxidation. In some embodiments, the passivation layer 130 includes a plurality of layers. For example, the passivation layer 130 includes a first high-k dielectric layer and a second high-k dielectric layer arranged below the first high-k dielectric layer. The passivation layer 130 may be a conformal layer. In some embodiments, the passivation layer 130 may be deposited to a thickness in a range from about 10 Å to about 100 Å. In some embodiments, as shown in FIG. 5, the passivation layer 130 also coats the lateral surfaces of the backside 110b of the device substrate in the BLC region 184 and/or the bonding pad region 186.

FIG. 6 illustrates a cross-sectional view 600 of an image sensor device during intermediate stages of manufacturing operations corresponding to operation 208, in accordance with some embodiments. Optionally, at operation 208, one or more dielectric layers, for example, the light transmission layer 134, may be formed over a surface of the substrate, for example, the backside 110b of the device substrate 110. The light transmission layer 134 may be formed on or over the passivation layer 130 (if present). The light transmission layer 134 may include an oxide, a nitride, a carbide, or the like. The light transmission layer 134 may fill the depressions defined by the interior surfaces 126a-b and extend along the backside 110b of the device substrate 110 into the BLC region 184 and/or the bonding pad region 186. The light transmission layer 134 may extend above the backside 110b of the device substrate to a thickness in a range from about 100 Å to about 1500 Å. The light transmission layer 134 may be deposited by any suitable process, for example, the light transmission layer 134 may be deposited by vapor deposition, such as CVD, PVD, PECVD, ALD, or the like. In some embodiments, the light transmission layer 134 may be deposited to a thickness in a range from about 1000 Å to about 2000 Å. The light transmission layer 134 may be a blanket layer. In addition, the angles of the plurality of interior surfaces 126a-b in combination with the light transmission layer 134 may increase absorption of radiation by the device substrate 110 (e.g., by reducing a reflection of radiation from the uneven surface). For example, for incident radiation 114 (e.g., incident radiation having a wavelength that is in a near infrared portion of the electromagnetic spectrum) having an angle of incidence greater than a critical angle, the plurality of interior surfaces 126a-b may act to reflect the incident radiation 114 to another one of the plurality of interior surfaces 126a-b, where the incident radiation 114 can be subsequently absorbed into the device substrate 110. The plurality of interior surfaces 126a-b may further act to reduce an angle of incidence for incident radiation 114 having a steep angle with respect to a top of the light transmission layer 134, thereby preventing the incident radiation 114 from reflecting from the device substrate 110.

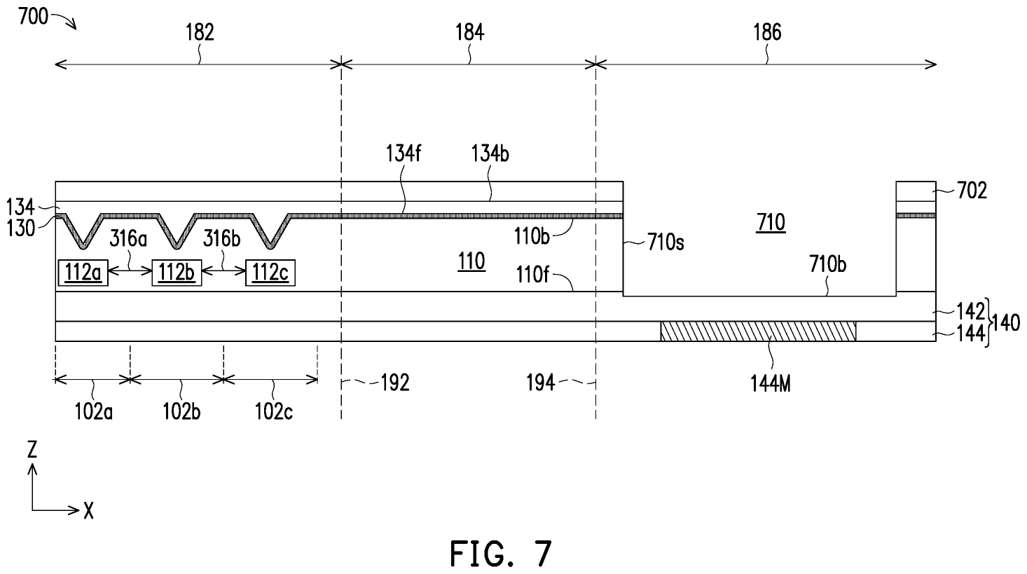

FIG. 7 illustrates a cross-sectional view 700 of an image sensor device during intermediate stages of manufacturing operations corresponding to operation 210, in accordance with some embodiments. At operation 210, a conductive bonding pad structure, for example, the conductive bonding pad structure 150, may be formed over an interconnect structure, for example, the interconnect structure 140. As shown in cross-sectional view 700 of FIG. 7, a second etching process is performed on the light transmission layer 134 along the backside 110b of the device substrate 110 according to a second patterned masking layer 702 of FIG. 7. The second etching process is performed by exposing the light transmission layer 134 and the underlying layers to one or more etchants with the second patterned masking layer 702 in place. The one or more etchants remove a portion of the light transmission layer 134, a portion of the passivation layer 130, and a portion of the device substrate 110 in the bonding pad region 186 to define a first opening 710. The first opening 710 extends from the backside 134b of the light transmission layer 134 through the STI layer 320 toward the interconnect structure 140, for example, the first opening 710 may extend toward the IMD layer 144. The first opening 710 is defined by sidewalls 710s and a bottom surface 710b. In some embodiments, as shown in FIG. 7, the sidewalls 710s of the opening 180 is defined by the light transmission layer 134, the passivation layer 130, and the device substrate 110. In some embodiments, as shown in FIG. 7, the bottom surface 710b of the first opening 710 is defined by the device substrate 110 and the STI layer 320. In some embodiments, where the STI layer 320 is not present, the bottom surface 710b of the first opening 710 may be defined by the device substrate 110 or the interconnect structure 140. In some embodiments, the second etching process may include a dry etching process. For example, the second etching process may include a coupled plasma etching process, such as an inductively coupled plasma (ICP) etching process or a capacitively coupled plasma (CCP) etching process. In other embodiments, the second etching process may comprise a wet etching process. After the second etching process, the second patterned masking layer 702 may be removed.

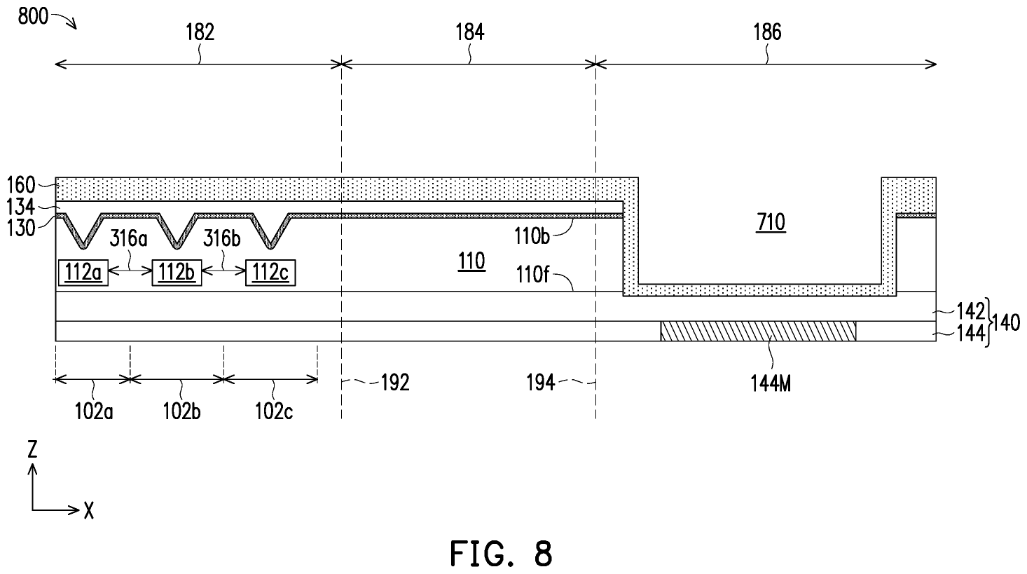

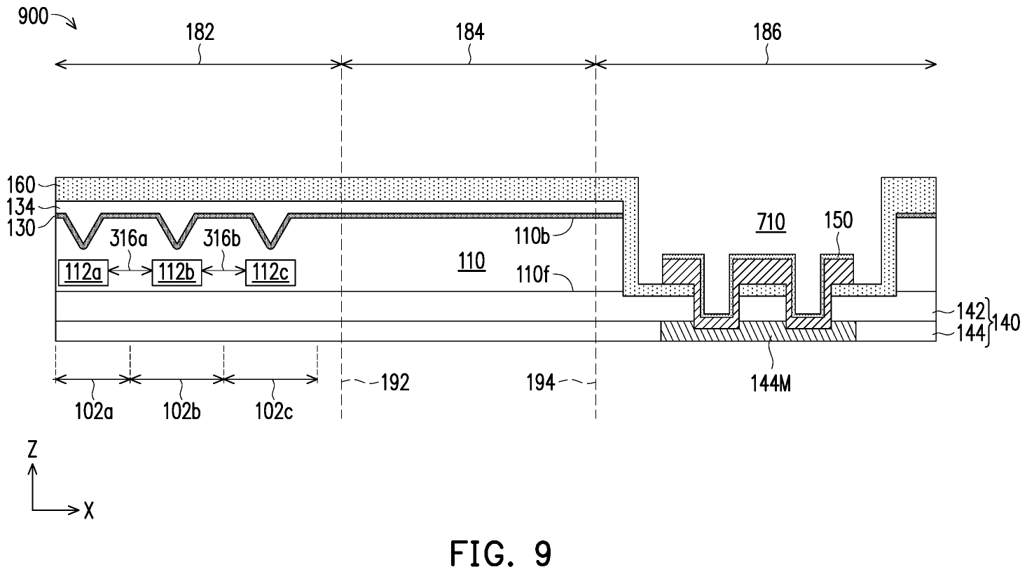

FIG. 8 illustrates a cross-sectional view 800 of an image sensor device during intermediate stages of manufacturing operations also corresponding to operation 210, in accordance with some embodiments. As operation 210 continues, a buffer oxide layer, for example, the buffer oxide layer 160, may be formed over the light transmission layer 134. In some embodiments, as shown in cross-sectional view 800 of FIG. 8, the buffer oxide layer 160 is formed over a remaining portion of the light transmission layer 134 in the pixel array region 182, the BLC region 184, and the bonding pad region 186, and extends into the first opening 710 over the sidewalls 710s and the bottom surface 710b. The buffer oxide layer 160 is formed in between the interconnect structure 140, or the STI layer 320 (if present) and the conductive bonding pad structure 150. As shown in FIG. 9, the buffer oxide layer 160 separates the conductive bonding pad structure 150 from the device substrate 110 while allowing the conductive bonding pad structure 150 to contact the conductive line 144M. In some embodiments, the buffer oxide layer 160 may be formed of silicon oxide, although other suitable dielectric materials may be used. In some embodiments, the buffer oxide layer 160 may be formed using ALD, CVD, PECVD, the like, or a combination thereof. In some embodiments, the buffer oxide layer 160 may be deposited to a thickness in a range from about 1000 Å to about 2000 Å.

FIG. 9 illustrates a cross-sectional view 900 of an image sensor device during intermediate stages of manufacturing operations also corresponding to operation 210, in accordance with some embodiments. As operation 210 continues, a conductive bonding pad structure, for example, the conductive bonding pad structure 150, may be formed in the first opening 710. The conductive bonding pad structure 150 is formed on the interconnect structure 140 in a manner so that the conductive bonding pad structure 150 is electrically coupled to the conductive lines 144M and separated from the sidewall of the device substrate 110 by the buffer oxide layer 160. The conductive bonding pad structure 150 may be used for forming an electrical connection, such as a wire bonding, to electrically couple to the circuits and the image-sensing elements 112a-c. For example, the conductive bonding pad structure 150 may be coupled to the image-sensing elements 112a-c through interconnect structure 140. The conductive bonding pad structure 150 may be formed by one or more deposition and patterning processes. In some embodiments, the conductive bonding pad structure 150 contains aluminum. In other embodiments, the conductive bonding pad structure 150 may contain another suitable metal, for example copper. A bonding wire (or another electrical interconnection element) may be attached to the conductive bonding pad structure 150 in a later process, and accordingly the conductive bonding pad structure 150 may also be referred to as a bond pad or a conductive pad.

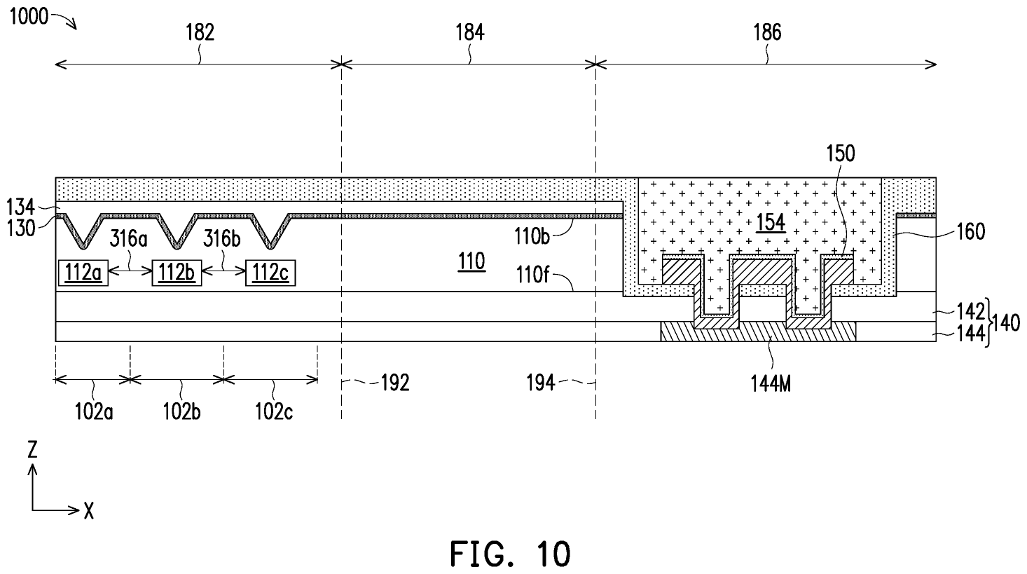

FIG. 10 illustrates a cross-sectional view 1000 of an image sensor device during intermediate stages of manufacturing operations also corresponding to operation 210, in accordance with some embodiments. As operation 210 continues, a dielectric fill material, for example, the dielectric fill material 154, may be deposited to fill the remainder of the first opening 710. The dielectric fill material 154 is formed to cover the conductive bonding pad structure 150 and to subsequently fill any peripheral openings. The dielectric fill material 154 is used to protect the conductive bonding pad structure 150 during subsequent processing steps and can be deposited by a blanket deposition process followed by a planarization process such that a top surface of the dielectric fill material 154 is planar or substantially planar.

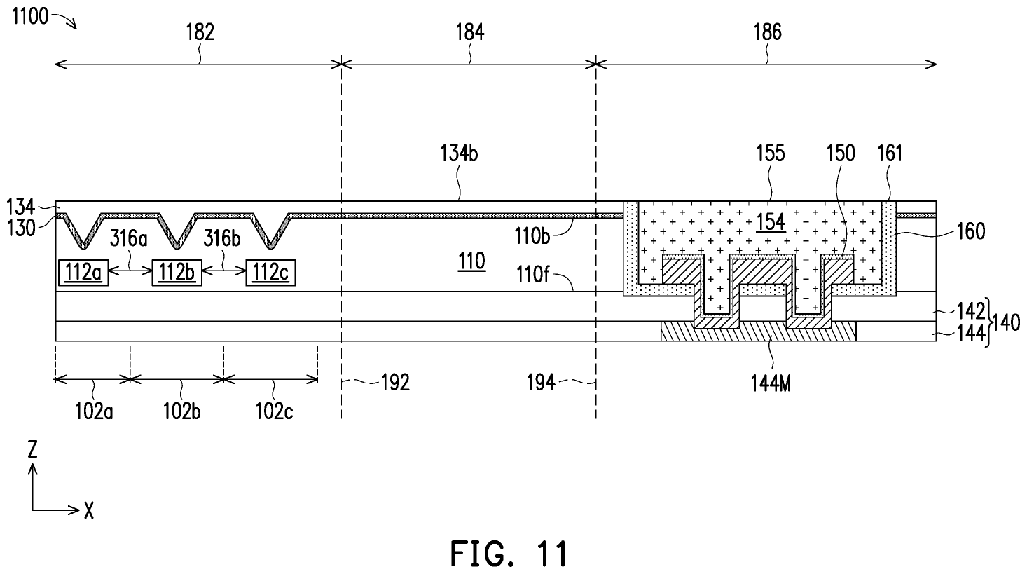

FIG. 11 illustrates a cross-sectional view 1100 of an image sensor device during intermediate stages of manufacturing operations also corresponding to operation 210, in accordance with some embodiments. As operation 210 continues, the dielectric fill material 154 and the buffer oxide layer 160 may be subjected to a planarization process, for example, a chemical mechanical planarization (“CMP”) process, to form a planar surface. In some embodiments, as shown in FIG. 11, the dielectric fill material 154 and the buffer oxide layer 160 above the light transmission layer 134 are removed such that a planarized top surface or the backside 134b of the light transmission layer 134 is co-planar or substantially co-planar with a planarized top surface 161 of the buffer oxide layer 160 and a planarized top surface 155 of the dielectric fill material 154. In other embodiments, a portion of the buffer oxide layer 160 above the light transmission layer 134 is removed to planarize the buffer oxide layer 160 such that a portion of the planarized buffer oxide layer 160 remains above the light transmission layer 134. In alternative embodiments, the buffer oxide layer 160, the light transmission layer 134, and the passivation layer 130 are removed such that a top surface of the light transmission layer 134 and the passivation layer 130 are both co-planar or substantially co-planar with the backside 110b of the device substrate 110.

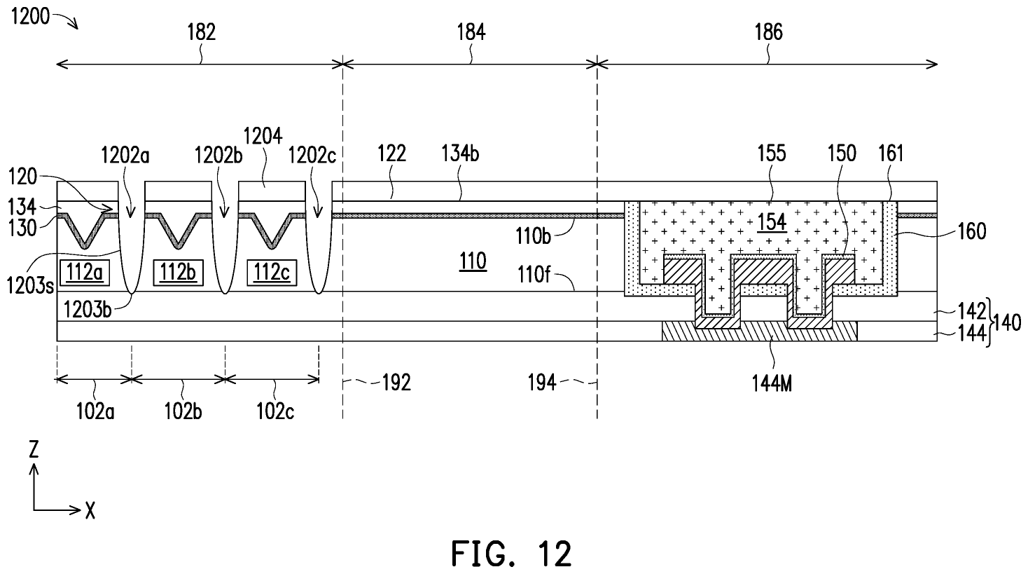

FIG. 12 illustrates a cross-sectional view 1200 of an image sensor device during intermediate stages of manufacturing operations corresponding to operation 212, in accordance with some embodiments. At operation 212, an isolation structure, for example, the isolation grid structure 120, is formed in a substrate, for example the device substrate 110. In some embodiments, the isolation grid structure 120 surrounds image-sensing elements formed in the substrate, for example, the image-sensing elements 112a-c formed in the device substrate 110. The isolation grid structure 120 includes an conductive oxide film. As shown in FIG. 12, a patterning process is performed to form trenches 1202a, 1202b, and 1202c (collectively 1202) within the backside 110b of the device substrate 110 between adjacent image-sensing elements 112a and 112b, between adjacent image-sensing elements 112b and 112c, and between image-sensing element 112c and the BLC region 184, respectively. The trenches 1202 include sidewalls 1203s defined by the device substrate 110 and a bottom surface 1203b that extends between the sidewalls 1203s. In some embodiments, the trenches 1202 extend from the backside 134b of the light transmission layer 134 through the passivation layer 130 and the device substrate 110 such that the sidewalls 1203s are defined by the light transmission layer 134, the passivation layer 130, and the device substrate 110. In some embodiments, the bottom surface 1203b is defined by the device substrate 110. In other embodiments where the trenches 1202 extend into additional layers formed on the frontside 110f of the device substrate 110, the bottom surface 1203b is defined by the additional layer, for example, the ILD layer 142. In some embodiments, one or more of the sidewalls 1203s can be tapered. In some embodiments, the trenches 1202 may be formed by etching processes (wet etching or dry etching) or photolithography patterning followed by reactive ion etching (RIE). In some embodiments, the device substrate 110 may be patterned by forming a third patterned masking layer 1204 on the backside 110b of the device substrate 110. The device substrate 110 is then exposed to an etchant in regions not covered by the third patterned masking layer 1204. The etchant etches the device substrate 110 to form the trenches 1202. In some embodiments, the trenches 1202 extend from the backside 110b of the substrate to a partial depth within the device substrate 110. In other embodiments, the trenches 1202 extend from the backside 110b to a full depth corresponding to the initial thickness 311 of the device substrate 110. In some embodiments, the trenches 1202 extend from the backside 110b of the device substrate 110 to a first depth 1206 within the device substrate 110. In some embodiments, the first depth 1206 is in a range from about 2 μm to about 10 μm, for example, from about 2 μm to about 6 μm. In some embodiments, the trenches 1202 have a width in a range from about 0.1 μm to about 0.4 μm. After the patterning process, the third patterned masking layer 1204 may be removed. In some embodiments, the trenches 1202 are formed at locations laterally removed from the image-sensing elements 112a-c. In some embodiments, the trenches 1202 laterally surround each of the image-sensing elements 112a-c.

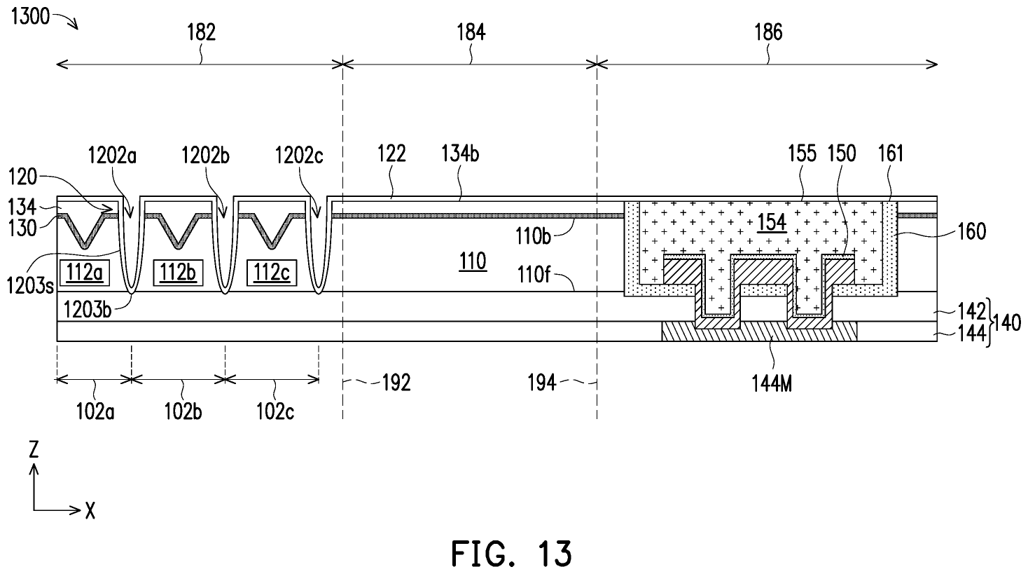

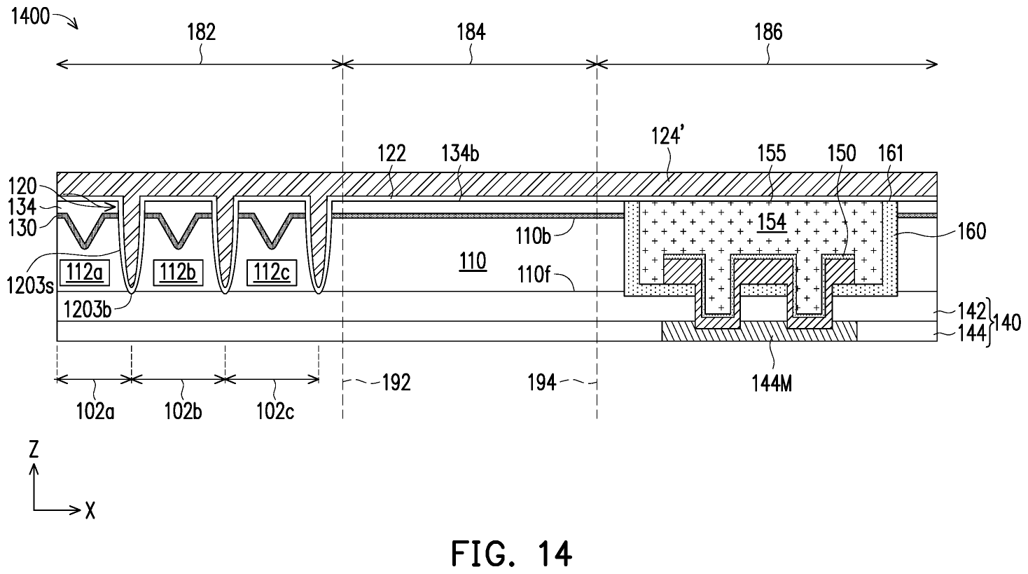

FIG. 13 illustrates a cross-sectional view 1300 of an image sensor device during intermediate stages of manufacturing operations also corresponding to operation 212, in accordance with some embodiments. As shown in FIG. 13, in some embodiments, the passivation liner 122 is deposited over the device substrate 110. The passivation liner 122 lines the sidewalls 1203s and the bottom surfaces 1203b of the trenches 1202. In some embodiments, as shown in cross-sectional view 1300 of FIG. 13, the passivation liner 122 is also formed over the remaining portion of the light transmission layer 134 in the pixel array region 182 and the BLC region 184, and further extends into the bonding pad region 186. The passivation liner 122 may serve a passivation function by separating the device substrate 110 from the subsequently deposited conductive material 124 (See FIG. 14). In addition, the passivation liner 122 may help alleviate crosstalk between adjacent light detection regions 102a-c. In some embodiments, the passivation liner 122 includes a high-k dielectric material, a dielectric material, or a multilayer combination thereof. In some embodiments, the passivation liner 122 may include a high-k dielectric material such as aluminum oxide, tantalum oxide, hafnium oxide, hafnium silicon oxide, hafnium aluminum oxide, hafnium tantalum oxide, titanium aluminum oxide, zirconium lanthanum oxide, or the like. In some embodiments, the passivation liner 122 includes the same material as the passivation layer 130. In other embodiments, the passivation liner 122 includes different material from the passivation layer 130. The passivation liner 122 may be deposited by vapor deposition, such as CVD or PVD, or grown by thermal oxidation. In some embodiments, the passivation liner 122 includes a plurality of layers. For example, the passivation liner 122 includes a first high-k dielectric layer and a second high-k dielectric layer arranged below the first high-k dielectric layer. In some embodiments, the passivation liner 122 may be deposited to a thickness in a range from about 10 Å to about 100 Å. The passivation liner 122 may be a conformal layer. In some embodiments, as shown in FIG. 13, the passivation liner 122 may extend upwardly from the trenches 1202 over the backside 110b of the device substrate 110 and be laterally disposed along the backside 110b of the device substrate 110. In other embodiments, the passivation liner 122 has a top surface coplanar with a lateral surface of the backside 110b of the device substrate 110.

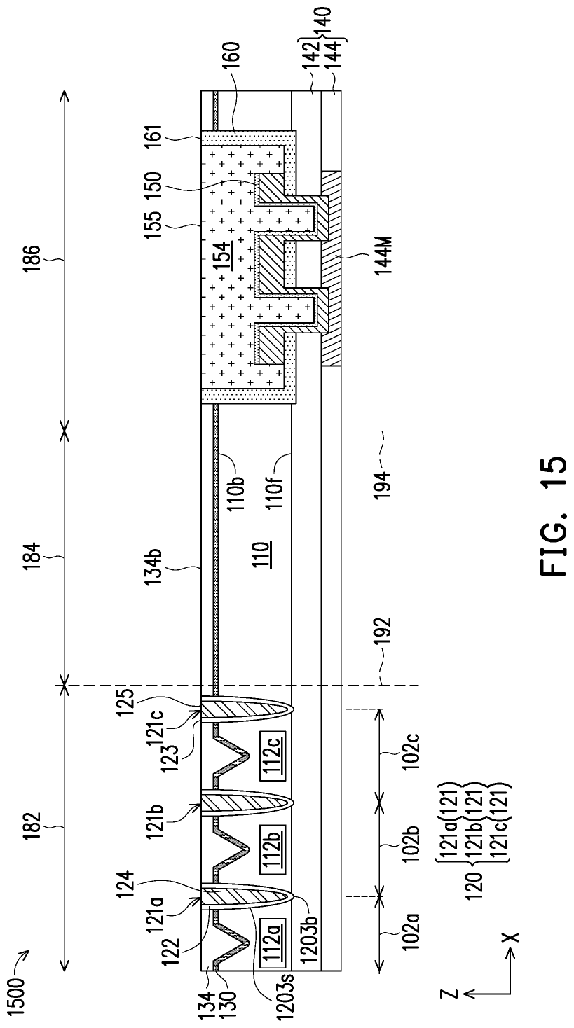

FIG. 14 illustrates a cross-sectional view 1400 of an image sensor device during intermediate stages of manufacturing operations also corresponding to operation 212, in accordance with some embodiments. As shown in FIG. 14, in some embodiments, an isolation material layer 124′ is deposited over the device substrate 110. The isolation material layer 124′ fills the trenches 1202 with the conductive material 124 to form the isolation grid structure 120. In some embodiments, as shown in cross-sectional view 1400 of FIG. 14, the isolation material layer 124′ is also formed over the passivation liner 122 in the pixel array region 182, the BLC region 184, and the bonding pad region 186. As shown in FIG. 15, the isolation grid structure 120 includes isolation structure segments 121a-c. In some embodiments, the isolation grid structure 120 may be a deep trench isolation (DTI) structure, such as a backside deep trench isolation (BDTI) structure. In some embodiments where the passivation liner 122 is present, the isolation grid structure 120 includes the passivation liner 122 and the conductive material 124. The conductive material 124 is deposited to fill the area of the trenches 1202 not filled by the passivation liner 122 (if present). The conductive material 124 may include a transparent conducting oxide, for example, a conductive oxide film. In some embodiments, the conductive material 124 has a refractive index (n) in a range from about 1.35 to about 1.8. Deposition of the conductive material 124 may involve a variety of techniques, such as chemical vapor deposition (CVD), plasma-enhanced chemical vapor deposition (PECVD), atmospheric pressure chemical vapor deposition (APCVD), low-pressure CVD (LPCVD), high density plasma CVD (HDPCVD), atomic layer CVD (ALCVD), sub-atmospheric CVD (SACVD), PVD, atomic layer deposition (ALD), sputtering, and/or other suitable operations. In some embodiments, the conductive material 124 includes one or more transparent conductive oxides (TCOs), directly deposited on the passivation liner 122. In some embodiments, the conductive material 124 includes a ITO film comprising a mixture of indium(III) oxide (In2O3) and tin(IV) oxide (SnO2). The ITO film may be formed by CVD or PVD.

FIG. 15 illustrates a cross-sectional view 1500 of an image sensor device during intermediate stages of manufacturing operations also corresponding to operation 212, in accordance with some embodiments. As shown in FIG. 15, in some embodiments, the isolation material layer 124′ is subjected to a planarization process, for example, a CMP process, to form a planar surface. In some embodiments, as shown in FIG. 15, the isolation material layer 124′ and the passivation liner 122 above the one or more dielectric layers 130 are removed such that a top surface 125 of the conductive material 124 is co-planar or substantially co-planar with a top surface 123 of the passivation liner 122 formed along the sidewalls 1203s of the trenches 1202 and the backside 134b of the light transmission layer 134 formed along the lateral surfaces of the backside 110b of the device substrate 110. In other embodiments, a portion of the isolation material layer 124′ above the passivation liner 122 is removed to planarize a top surface of the conductive material 124 such that a portion of the conductive material 124 remains above a top surface of the passivation liner 122. In alternative embodiments, the isolation material layer 124′, the passivation liner 122, the light transmission layer 134, and the passivation layer 130 are removed such that a top surface 125 of the conductive material 124 and a top surface 123 of the passivation liner 122 are both co-planar or substantially co-planar with the backside 110b of the device substrate 110.

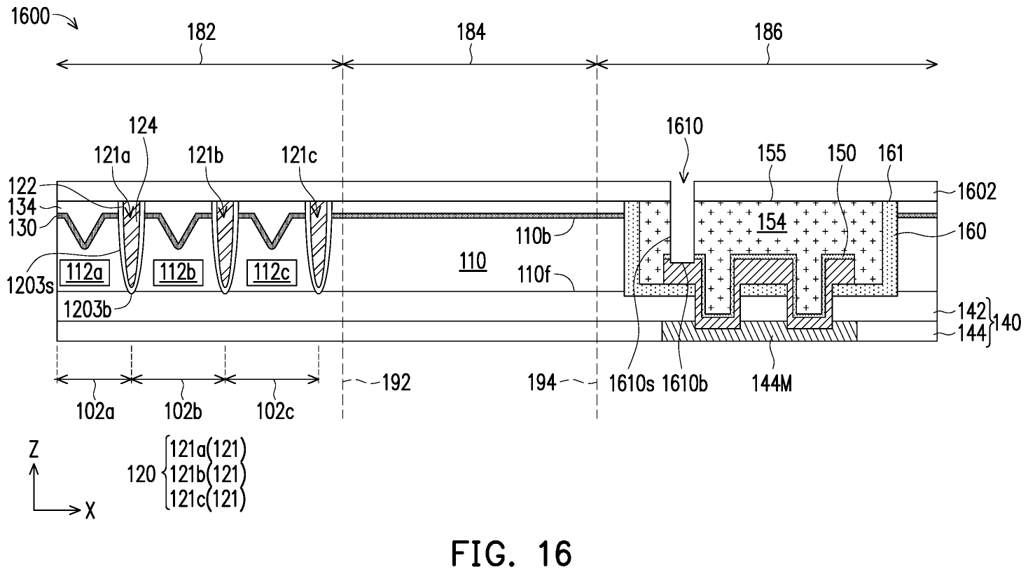

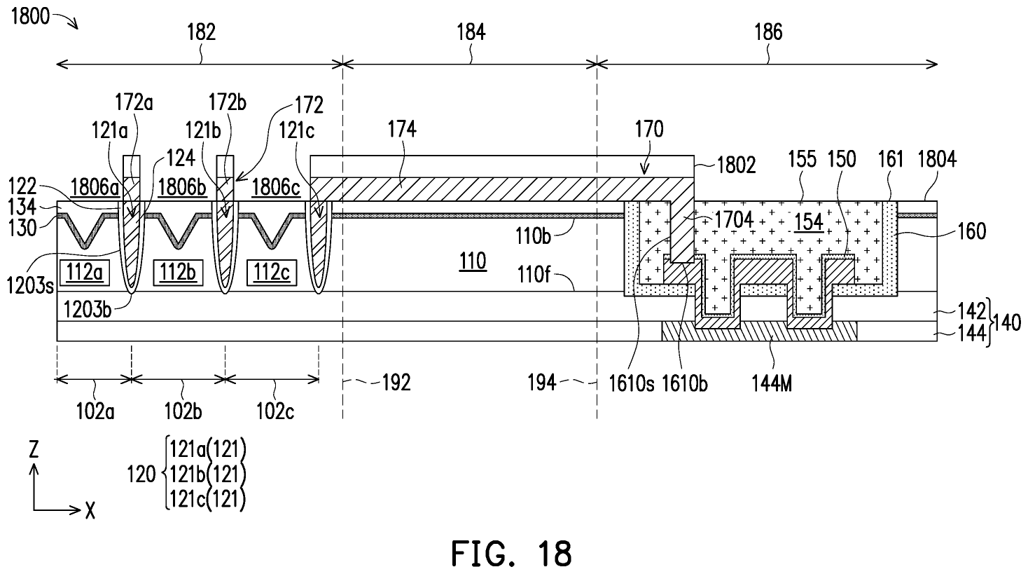

FIG. 16 illustrates a cross-sectional view 1600 of an image sensor device during intermediate stages of manufacturing operations corresponding to operation 214, in accordance with some embodiments. At operation 214, a bias pad layer, for example, the bias pad layer 174 (see FIG. 18), may be formed over a substrate, for example, the device substrate 110. As shown in cross-sectional view 1600 of FIG. 16, a fourth etching process is performed on the dielectric fill material 154 to expose the conductive bonding pad structure 150 according to a fourth patterned masking layer 1602 of FIG. 16. The fourth etching process is performed by exposing the dielectric fill material 154 to one or more etchants with the fourth patterned masking layer 1602 in place. The one or more etchants remove a portion of the dielectric fill material 154 in the bonding pad region 186 to define a second opening 1610. The second opening 1610 extends from a top surface 155 of the dielectric fill material 154 to the conductive bonding pad structure 150. The second opening 1610 is defined by sidewalls 1610s and a bottom surface 1610b. In some embodiments, as shown in FIG. 16, the sidewalls 1610s of the second opening 1610 are defined by the dielectric fill material 154. In some embodiments, as shown in FIG. 16, the bottom surface 1610b of the second opening 1610 is defined by the conductive bonding pad structure 150. In some embodiments, the second opening 1610 has a width in a range from about 0.3 μm to about 5 μm. In some embodiments, the fourth etching process may include a dry etching process. For example, the fourth etching process may include a coupled plasma etching process, such as an inductively coupled plasma (ICP) etching process or a capacitively coupled plasma (CCP) etching process. In other embodiments, the fourth etching process may include a wet etching process. After the fourth etching process, the fourth patterned masking layer 1602 may be removed. In some embodiments, the second openings 1610 are selectively formed over the conductive bonding pad structure 150 that is designed to apply a bia voltage to the isolation grid structure 120.

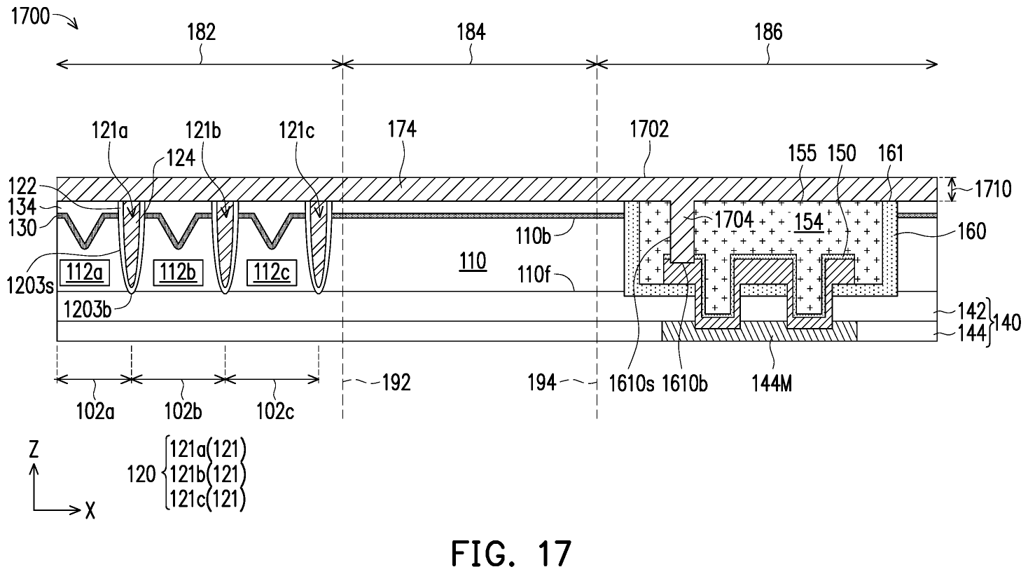

FIG. 17 illustrates a cross-sectional view 1700 of an image sensor device during intermediate stages of manufacturing operations also corresponding to operation 214, in accordance with some embodiments. As shown in FIG. 17, a conductive layer 1702 is deposited over the device substrate 110. In some embodiments, as shown in FIG. 17, the conductive layer 1702 extends across the pixel array region 182, the BLC region 184, and the bonding pad region 186. In some embodiments, the conductive layer 1702 fills the second opening 1610 thereby forming a bias pad connection 1704, which electrically couples the conductive bonding pad structure 150 with the isolation grid structure 120 via the conductive layer 1702. The conductive layer 1702 may be a metal layer. In some embodiments, the conductive layer 1702 is made of a reflective metal material or a light absorption material. For example, the conductive layer 1702 may include tungsten, copper, gold, silver, aluminum, nickel, alloys thereof, or the like and may be formed using PVD, plating, or the like. In some embodiments, the conductive layer 1702 may be deposited to a thickness 1710 in a range from about 1000 Å to about 3000 Å.

FIG. 18 illustrates a cross-sectional view 1800 of an image sensor device during intermediate stages of manufacturing operations also corresponding to operation 214, in accordance with some embodiments. As shown in cross-sectional view 1800 of FIG. 18, the conductive layer 1702 is patterned to form the bias pad structure 170. The bias pad structure 170 includes the light blocking grid section 172 in the pixel array region 182 and the bias pad layer 174 in the BLC region 184. In some embodiments, a fifth etching process is performed on the conductive layer 1702 to pattern the conductive layer 1702 according to a fifth patterned masking layer 1802 of FIG. 18. The fifth etching process is performed by exposing the conductive layer 1702 to one or more etchants with the fifth patterned masking layer 1802 in place. The one or more etchants remove exposed portions of the conductive layer 1702 exposing the underlying materials. In some embodiments, the fifth etching process may include a dry etching process. For example, the fifth etching process may include a coupled plasma etching process, such as an inductively coupled plasma (ICP) etching process or a capacitively coupled plasma (CCP) etching process. In other embodiments, the fifth etching process may comprise a wet etching process. After the fifth etching process, the fifth patterned masking layer 1802 may be removed.

In some embodiments, the conductive layer 1702 is patterned to define the light blocking grid section 172 in the pixel array region 182. The light blocking grid section 172 includes the light blocking grid segment 172a and the light blocking grid segment 172b. In some embodiments, the light blocking grid segments 172a, 172b have a thickness in a range from about 1000 Å to about 3000 Å and a width in a range from about 0.1 micrometers to about 0.3 micrometers. In some embodiments, the light blocking grid section 172 is formed over the isolation grid structure 120. For example, as shown in FIG. 18, the light blocking grid segment 172a is formed over the isolation grid segment 121a and the light blocking grid segment 172b is formed over the isolation grid segment 121b. In some embodiments, the conductive layer 1702 is patterned to expose the top surface 155 of the dielectric fill material 154, a top surface 161 of the buffer oxide layer 160, and a top surface 1804 of the light transmission layer 134 in the bonding pad region 186. In some embodiments, the conductive layer 1702 is not patterned in the BLC region 184. The bias pad layer 174 extends from the pixel array region 182, through the BLC region 184, and into the bonding pad region 186.

The bias pad structure 170 includes the light blocking grid section 172 in the pixel array region 182 and the bias pad layer 174 in the BLC region 184. The light blocking grid section 172 may prevent optical crosstalk between adjacent image-sensing elements 112a-c. The bias pad layer 174 may cover any reference pixels present in the BLC region 184. For example, the bias pad layer 174 may cover the entirety of the backside 134b of the light transmission layer 134 in the BLC region 184. In addition, the bias pad layer 174 may electrically couple the isolation grid structure 120 with the conductive bonding pad structure 150 such that the isolation structure can be biased using the conductive bonding pad structure 150. For example, as shown in FIG. 18, the bias pad layer 174 electrically couples the conductive bonding pad structure 150 with isolation grid segment 121c, which also allows biasing of isolation grid segments 121a and 121b, and the light blocking grid segments 172a-b of the light blocking grid section 172 positioned over the isolation grid segments 121a and 121b, respectively. The light blocking grid segments 172a, 172b surround outer perimeters of the plurality of image-sensing elements 112a-c, such that a plurality of first openings 1806a, 1806b, and 1806c defined by the light blocking grid segments 172a, 172b overlie the plurality of image-sensing elements 112a-c.

FIG. 19A illustrates a cross-sectional view 1900 of an image sensor device during intermediate stages of manufacturing operations corresponding to operation 216, in accordance with some embodiments. As shown in cross-sectional view 1900 of FIG. 19A, a dielectric planarization layer 1902 may be formed over a substrate, for example, over the light transmission layer 134. The dielectric planarization layer 1902 may have a planar or substantially planar upper surface 1902u. The dielectric planarization layer 1902 may include one or more stacked dielectric layers. The dielectric planarization layer 1902 may include an oxide, a nitride, a carbide, or the like. In particular embodiments, the dielectric planarization layer 1902 includes an oxide (e.g., SiO2). The dielectric planarization layer 1902 may be formed over the light transmission layer 134 and the light blocking grid section 172 in the pixel array region 182. The dielectric planarization layer 1902 may extend along the bias pad layer 174 into the BLC region 184 and/or into the bonding pad region 186 as shown in FIG. 19A. The dielectric planarization layer 1902 may be deposited by any suitable process, for example, the dielectric planarization layer 1902 may be deposited by vapor deposition, such as CVD, PVD, PECVD, ALD, or the like. In some embodiments, the dielectric planarization layer 1902 may be deposited to a thickness 1903 in a range from about 4000 Å to about 6000 Å. The dielectric planarization layer 1902 may be deposited as a blanket layer.

In some embodiments where no additional grid layers are formed over the light blocking grid section 172, operation 218 is skipped and the method 200 proceeds from operation 216 to operation 220.

FIG. 19B illustrates a cross-sectional view 1910 of an image sensor device during intermediate stages of manufacturing operations corresponding to operation 220, in accordance with some embodiments. At operation 220, a bonding pad structure, for example, the conductive bonding pad structure 150, may be exposed. As shown in cross-sectional view 1910 of FIG. 19B, a sixth etching process is performed on dielectric planarization layer 1902 and the dielectric fill material 154 to expose the conductive bonding pad structure 150 according to a sixth patterned masking layer 1912 of FIG. 19B. The sixth etching process is performed by exposing the dielectric planarization layer 1902 and the dielectric fill material 154 to one or more etchants with the sixth patterned masking layer 1912 in place. The one or more etchants remove a portion of the dielectric planarization layer 1902 and the dielectric fill material 154 in the bonding pad region 186 to define a third opening 1914. The third opening 1914 extends from the upper surface 1914u of the dielectric planarization layer 1902 to the conductive bonding pad structure 150. The third opening 1914 is defined by sidewalls 1914s and a bottom surface 1914b. In some embodiments, as shown in FIG. 19B, the sidewalls 1914s of the third opening 1914 are defined by the dielectric planarization layer 1902 and the dielectric fill material 154. In some embodiments, as shown in FIG. 19B, the bottom surface 1914b of the third opening 1914 is defined by the conductive bonding pad structure 150. In some embodiments, the third opening 1914 has a width in a range from about 0.3 μm to about 5 μm. In some embodiments, the sixth etching process may include a dry etching process. For example, the sixth etching process may include a coupled plasma etching process, such as an inductively coupled plasma (ICP) etching process or a capacitively coupled plasma (CCP) etching process. In other embodiments, the sixth etching process may comprise a wet etching process. After the sixth etching process, the sixth patterned masking layer 1912 may be removed.

FIG. 19C illustrates a cross-sectional view 1920 of an image sensor device during intermediate stages of manufacturing operations corresponding to operation 222 and operation 224, in accordance with some embodiments. At operation 222, a color filter layer 1930 may be formed over the dielectric planarization layer 1902 in the pixel array region 182. In some embodiments, the color filter layer 1930 includes a plurality of color filters 1930a-c, aligned with respective light detection regions 102a-c. The color filters 1930a-c may be used to allow specific wavelengths of light to pass while reflecting other wavelengths, thereby allowing the image sensor device to determine the color of the light being received by the light detection regions 102a-c. For example, the color filters 1930a-c may be a red, green, and blue filter as used in a Bayer pattern. Other combinations, such as cyan, yellow, and magenta, may also be used. The number of different colors of the color filters 1930a-c may also vary. The color filters 1930a-c may comprise a polymeric material or resin, such as polymethyl-methacrylate (PMMA), polyglycidyl-methacrylate (PGMA), or the like, which includes colored pigments.

Still referring to FIG. 19C, at operation 224, in some embodiments, an array of micro-lenses 1940a-c is formed over the color filter layer 1930 and aligned with respective color filters 1930a-c and respective light detection regions 102a-c. The micro-lenses 1940a-c may be formed of any material that may be patterned and formed into lenses, such as a high transmittance acrylic polymer. In some embodiments, a micro-lens layer may be formed using a material in a liquid state by, for example, spin-on techniques. Other methods, such as CVD, PVD, or the like, may also be used. The planar material for the micro-lens layer may be patterned using suitable photolithography and etching methods to pattern the planar material in an array corresponding to the array of the light detection regions 102a-c. The planar material may then be reflowed to form an appropriate curved surface for the micro-lenses 1940a-c. Subsequently, the micro-lenses 1940a-c may be cured using, for example, a UV treatment. In some embodiments, after forming the micro-lenses 1940a-c, the image sensor device may undergo further processing such as, for example, packaging.

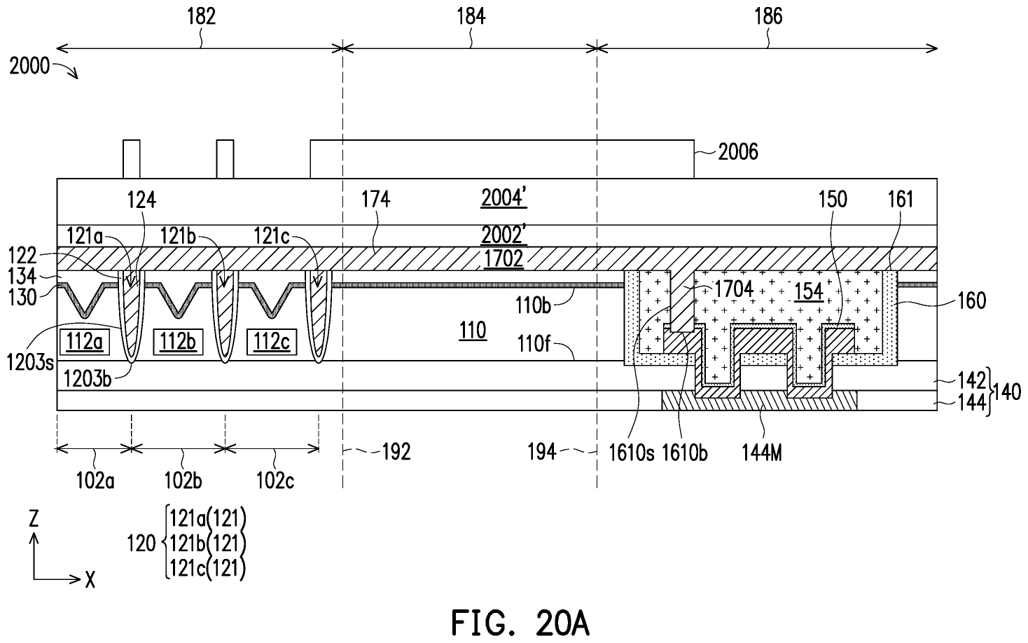

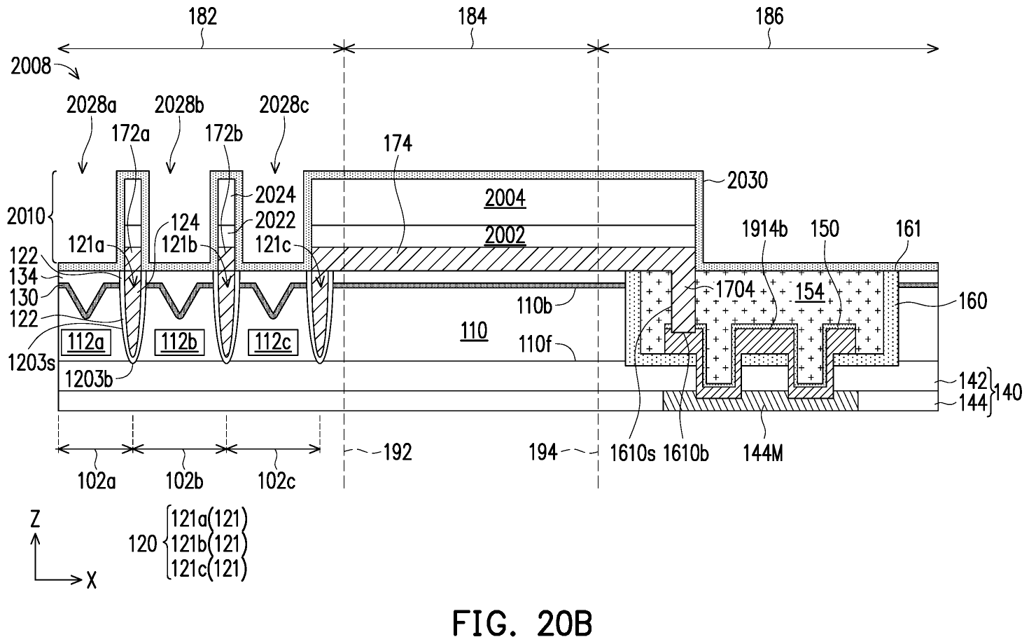

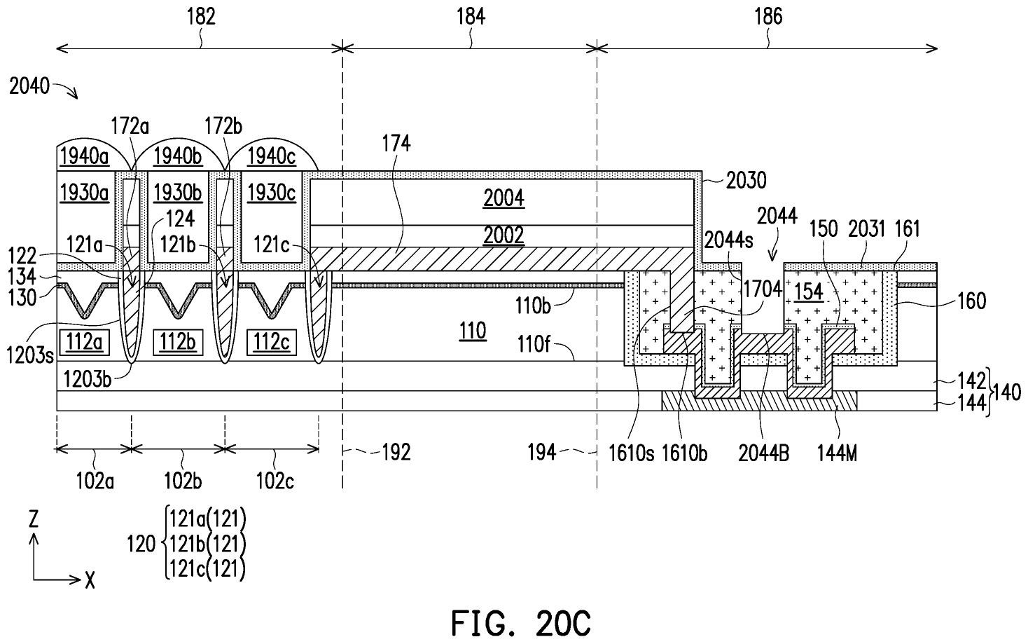

FIGS. 20A-20C illustrate an image sensor device during intermediate stages of manufacturing operations, in accordance with some embodiments. At operation 218, in some embodiments, an upper grid structure 2010 (see FIG. 20B) is formed over the isolation grid structure 120. In some embodiments, the upper grid structure 2010 is a composite grid structure. The upper grid structure 2010 may include a metal grid section, a first dielectric section, and/or a second dielectric section. In some embodiments, the upper grid structure 2010 may have a tetragon shape or circular shape from a top view. In some embodiments, the upper grid structure 2010 is vertically aligned with the isolation grid structure 120 as is shown in FIGS. 20A-20C. In some embodiments, the upper grid structure 2010 is vertically aligned with the isolation grid structure 120 and a width or diameter of the upper grid structure may be identical or substantially identical to a width or a diameter of the image-sensing element 112a-c. In other embodiments, the upper grid structure 2010 is laterally shifted or offset (e.g., along the x-axis) relative to the isolation grid structure 120.

FIG. 20A illustrates a cross-sectional view 2000 of an image sensor device during intermediate stages of manufacturing operations corresponding to operation 218, in accordance with some embodiments. In some embodiments, a first dielectric layer 2002′ may be formed above the conductive layer 1702 when a composite grid is to be formed. In some embodiments, the first dielectric layer 2002′ is an oxide, for example, silicon oxide (e.g., SiO2) or hafnium oxide (HfO2), or a material with a refractive index less than silicon. In other embodiments, the first dielectric layer 2002′ may be a nitride or an oxynitride, for example, silicon nitride or silicon oxynitride. In some embodiments, the first dielectric layer 2002′ includes the same material as the light transmission layer 134. In other embodiments, the first dielectric layer 2002′ includes a material different from the material of the light transmission layer 134. The first dielectric layer 2002′ may be formed by a variety of techniques, such as CVD, PVD, atomic layer deposition (ALD), plasma-enhanced chemical vapor deposition (PECVD), atmospheric pressure chemical vapor deposition (APCVD), low-pressure CVD (LPCVD), high density plasma CVD (HDPCVD), atomic layer CVD (ALCVD), sub-atmospheric CVD (SACVD), and/or other suitable operations. The first dielectric layer 2002′ may have a thickness in a range from about 100 Å to about 1000 Å, for example, in a range from about 300 Å to about 800 Å.

A second dielectric layer 2004′ may be formed over the first dielectric layer 2002′. In some embodiments, the second dielectric layer 2004′ is an oxide, for example, silicon oxide (e.g., SiO2) or hafnium oxide (HfO2), or a material with a refractive index less than silicon. In other embodiments, the second dielectric layer 2004′ may be a nitride or an oxynitride, for example, silicon nitride or silicon oxynitride. In particular embodiments, the second dielectric layer 2004′ is a silicon oxynitride layer. The second dielectric layer 2004′ may be formed using any of the techniques described with reference to the first dielectric layer 2002′. In some embodiments, the second dielectric layer 2004′, includes a material different from the material of the first dielectric layer 2002′. In some embodiments, the second dielectric layer 2004′ includes the same material as the light transmission layer 134. In other embodiments, the second dielectric layer 2004′ includes a material different from the material of the light transmission layer 134. In some embodiments, the second dielectric layer 2004′ has a thickness greater than the thickness of the first dielectric layer 2002′. The second dielectric layer 2004′ may have a thickness in a range from about 1000 Å to about 3000 Å, for example, from about 1500 Å to about 2000 Å.

FIG. 20B illustrates a cross-sectional view 2008 of an image sensor device during intermediate stages of manufacturing operations also corresponding to operation 218, in accordance with some embodiments. Referring to FIG. 20A and FIG. 20B, subsequently, one or more patterning operations are performed, wherein the conductive layer 1702, the first dielectric layer 2002′, and the second dielectric layer 2004′ are patterned by one or more masking layers 2006 to form the upper grid structure 2010. Specifically, the conductive layer 1702 is patterned to form the bias pad layer 174 and the light blocking grid section 172 which includes the light blocking grid segments 172a-b, the first dielectric layer 2002′ is patterned to form a first blanket dielectric layer 2002 and a first dielectric grid section 2022, and the second dielectric layer 2004′ is patterned into a second blanket dielectric layer 2004 and a second dielectric grid section 2024. It should be noted that the light blocking grid section 172, the first dielectric grid section 2022, and the second dielectric grid section 2024 may have a circular shape or a tetragon shape from a top view perspective. In some embodiments, as shown in FIG. 20B, the light blocking grid section 172, the first dielectric grid section 2022, and the second dielectric grid section 2024 (which form the upper grid structure 2010) are vertically aligned with the isolation grid structure 120 to improve the alignment between an arrangement of each of the image-sensing elements 112 and an arrangement of the corresponding upper grid structure 2010. In some embodiments, the upper grid structure 2010 defines openings 2028a-c in which color filters 1930a-c are subsequently formed (see FIG. 20C). The masking layer 2006 is subsequently removed.

Still referring to FIG. 20B, in some embodiments, a dielectric capping layer 2030 is formed over the exposed surfaces of the image sensor device and the upper grid structure 2010. In some embodiments, as shown in FIG. 20B, the dielectric capping layer 2030 lines the upper grid structure 2010 spacing the subsequently formed color filters 1930a-c from the upper grid structure 2010. Thereby the upper grid structure 2010 is inside the dielectric capping layer 2030 and surrounded by the dielectric capping layer 2030. The dielectric capping layer 2030 may be the same material or a different material than the first dielectric grid section 2022 and/or the second dielectric grid section 2024. The dielectric capping layer 2030 may include oxide, such as silicon oxide (SiO2), hafnium oxide (HfO2), or the like. In other embodiments, the dielectric capping layer 2030 may be a nitride or oxynitride, for example, silicon nitride or silicon oxynitride. In some embodiments, the dielectric capping layer 2030 may include or be silicon nitride, silicon oxynitride, silicon oxycarbide, silicon carbonitride, silicon carbon oxide, silicon carboxynitride, carbon nitride, silicon oxide, hafnium oxide, a combination thereof, or the like. In some embodiments, the dielectric capping layer 2030 may be a conformal layer. In some embodiments, the dielectric capping layer 2030 has a thickness that is less than the thickness of the second dielectric layer 2004′. In some embodiments, the dielectric capping layer 2030 has a thickness that is less than the thickness of the first dielectric layer 2002′. The dielectric capping layer 2030 may have a thickness in a range from about 1000 Å to about 2000 Å, for example, from about 1500 Å to about 1800 Å.

FIG. 20C illustrates a cross-sectional view 2040 of an image sensor device during intermediate stages of manufacturing operations corresponding to operation 220, in accordance with some embodiments. At operation 220, a bonding pad structure, for example, the conductive bonding pad structure 150, may be exposed. As shown in cross-sectional view 2040 of FIG. 20C, a seventh etching process is performed on the dielectric capping layer 2030 and the dielectric fill material 154 to expose the conductive bonding pad structure 150. The seventh etching process may be performed using a patterned mask layer as previously discussed herein. The seventh etching process is performed by exposing the dielectric capping layer 2030 and the dielectric fill material 154 to one or more etchants with a patterned masking layer in place. The one or more etchants remove a portion of the dielectric capping layer 2030 and the dielectric fill material 154 in the bonding pad region 186 to define a fourth opening 2044. The fourth opening 2044 extends from a top surface 2031 of the dielectric capping layer 2030 to the conductive bonding pad structure 150. The fourth opening 2044 is defined by sidewalls 2044s and a bottom surface 2044b. In some embodiments, as shown in FIG. 20C, the sidewalls 2044s of the fourth opening 2044 are defined by the dielectric capping layer 2030 and the dielectric fill material 154. In some embodiments, as shown in FIG. 20C, the bottom surface 2044b of the fourth opening 2044 is defined by the conductive bonding pad structure 150. In some embodiments, the fourth opening 2044 has a width in a range from about 0.3 μm to about 5 μm.

Still referring to FIG. 20C, FIG. 20C also illustrates an image sensor device during intermediate stages of manufacturing operations corresponding to operation 222 and operation 224, in accordance with some embodiments. At operation 222, a color filter layer 1930 may be formed over the dielectric capping layer 2030 in the pixel array region 182. In some embodiments, as shown in FIG. 20C, color filters 1930a-c are formed in the opening 2028a-c which are defined by the upper grid structure 2010. At operation 224, the array of micro-lenses 1940a-c may be formed over the color filter layer 1930 and aligned with respective color filters 1930a-c and respective light detection regions 102a-c. In some embodiments, after forming the micro-lenses 1940a-c, the image sensor device may undergo further processing such as, for example, packaging.

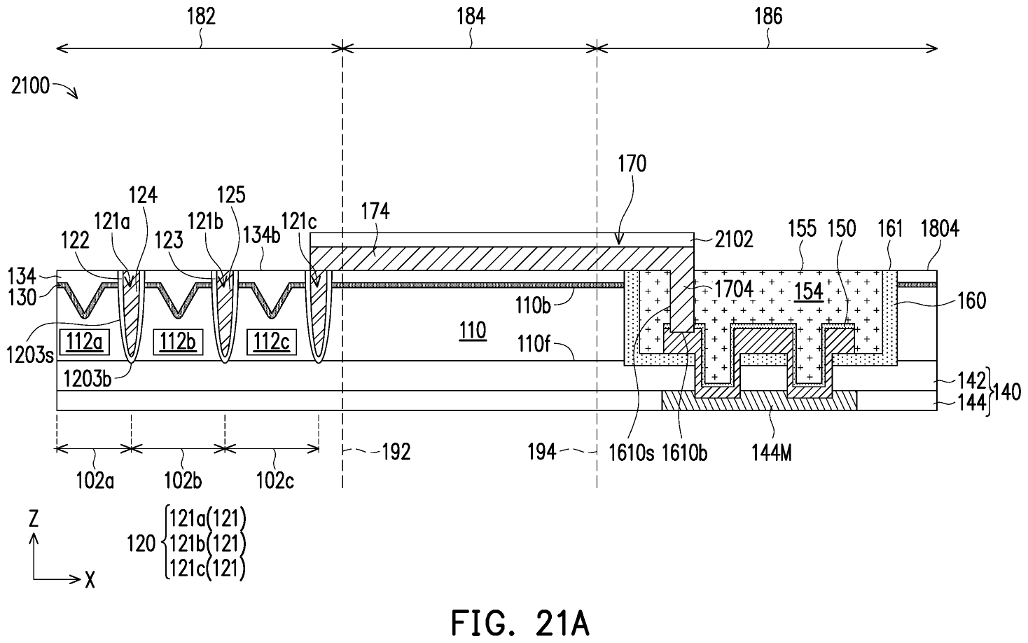

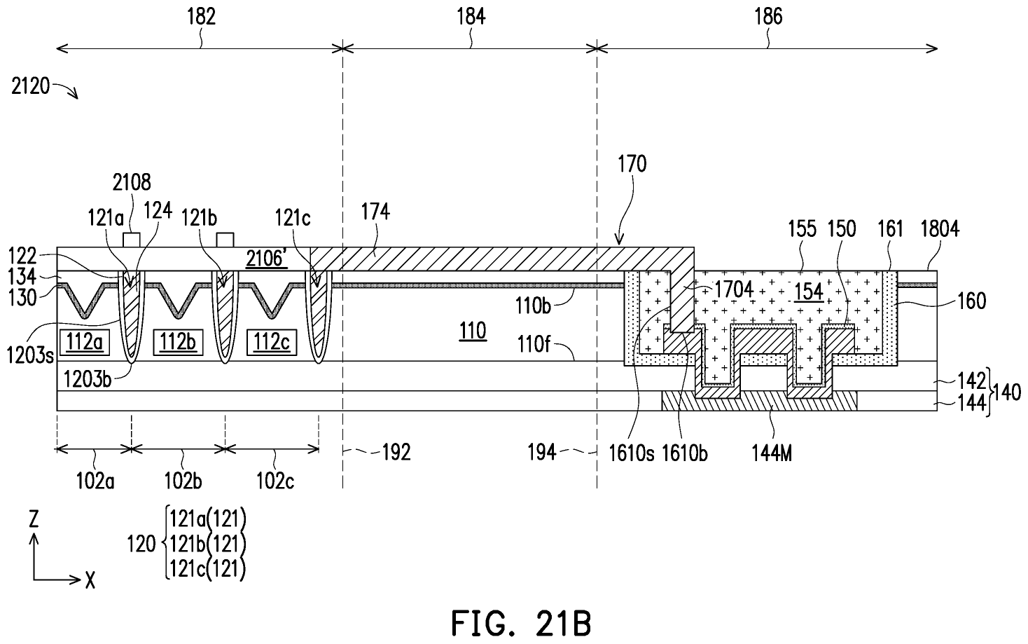

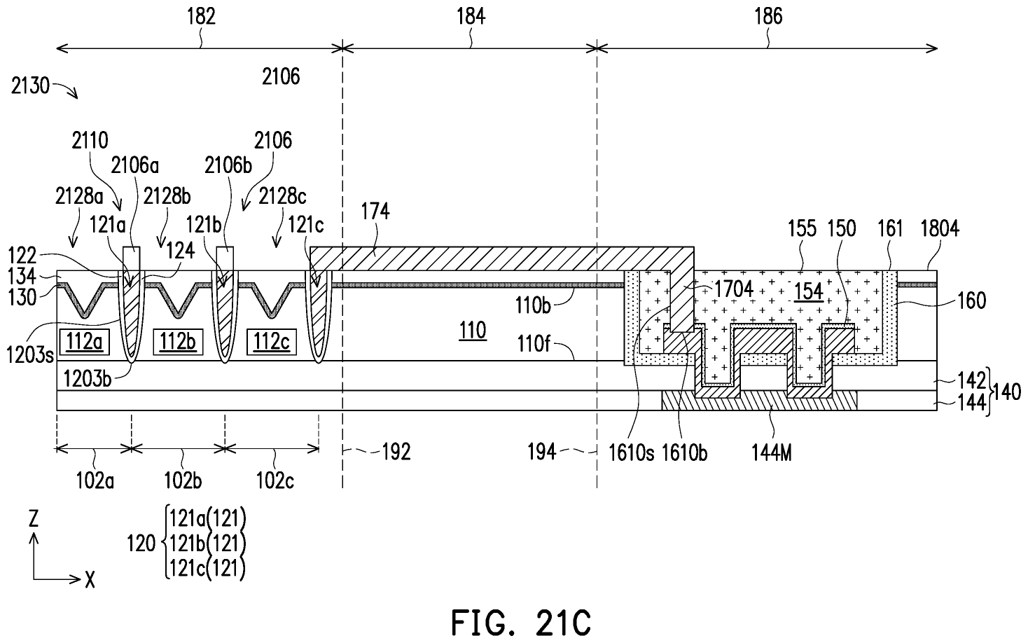

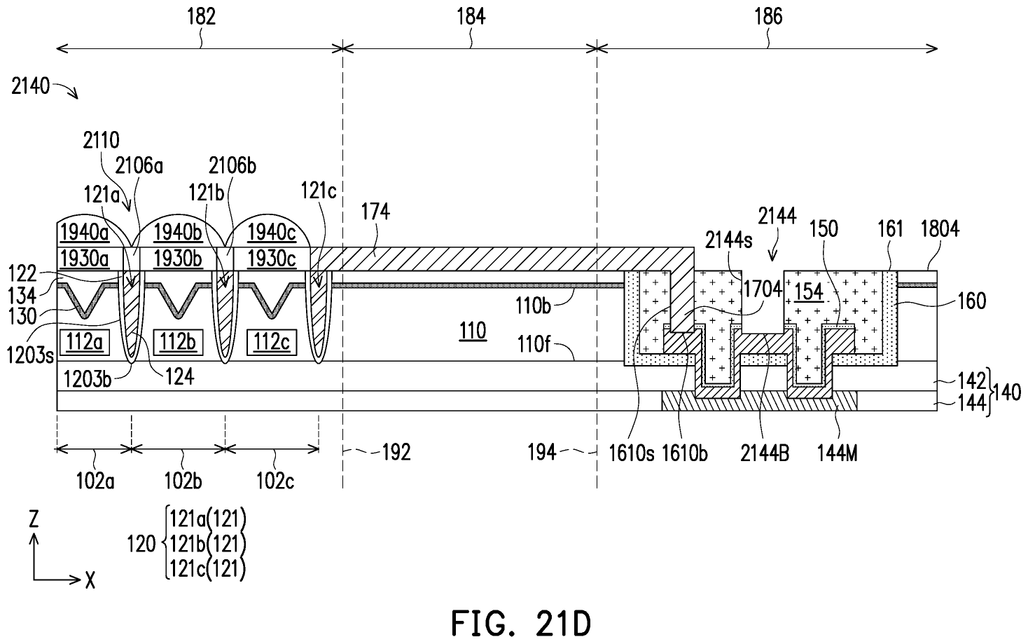

FIGS. 21A-21D illustrate an image sensor device during intermediate stages of manufacturing operations, in accordance with some embodiments. FIGS. 21A-21D depict another embodiment in which an upper grid structure 2110 (see FIG. 21C) is formed over the isolation grid structure 120. The upper grid structure 2110 includes a low refractive index material or low-n material. The low-n material has a refractive index less than the refractive index of the color filters 1930a-c. Due to the low refractive index, the low-n material isolates neighboring color filters 1930a-c and directs light to the color filters to increase the effective size of the color filters 1930a-c. In some embodiments, the upper grid structure 2110 may have a tetragon shape or circular shape from a top view. In some embodiments, the upper grid structure 2110 is vertically aligned with the isolation grid structure 120 as is shown in FIGS. 21C-21D. In some embodiments, the upper grid structure 2110 is vertically aligned with the isolation grid structure 120 and a width or diameter of the upper grid structure may be identical or substantially identical to a width or a diameter of the image-sensing element 112a-c. In other embodiments, the upper grid structure 2110 is laterally shifted or offset (e.g., along the x-axis) relative to the isolation grid structure 120.

FIG. 21A illustrates a cross-sectional view 2100 of an image sensor device during intermediate stages of manufacturing operations corresponding to operation 214, in accordance with some embodiments. As shown in cross-sectional view 2100 of FIG. 21A, the conductive layer 1702 is patterned to form the bias pad structure 170. The bias pad structure 170 includes the bias pad layer 174 in the BLC region 184. In some embodiments, an eighth etching process is performed on the conductive layer 1702 to pattern the conductive layer 1702 according to an eighth patterned masking layer 2102 of FIG. 21A. The eighth etching process is performed by exposing the conductive layer 1702 to one or more etchants with the eighth patterned masking layer 2102 in place. The one or more etchants remove exposed portions of the conductive layer 1702 exposing the underlying materials. In some embodiments, the eighth etching process may include a dry etching process. For example, the eighth etching process may include a coupled plasma etching process, such as an inductively coupled plasma (ICP) etching process or a capacitively coupled plasma (CCP) etching process. In other embodiments, the eighth etching process may comprise a wet etching process. After the eighth etching process, the eighth patterned masking layer 2102 may be removed.

In some embodiments, as shown in FIG. 21A, the conductive layer 1702 is patterned to expose the backside 134b of the light transmission layer 134, the top surface 123 of the passivation liner 122, and the top surface 125 of the conductive material 124 in the pixel array region 182. In some embodiments, the conductive layer 1702 is removed from the pixel array region 182 during the patterning process. In some embodiments, as is also shown in FIG. 21A, the conductive layer 1702 is patterned to expose the top surface 155 of the dielectric fill material 154, the top surface 161 of the buffer oxide layer 160, and the top surface 1804 of the light transmission layer 134 in the bonding pad region 186. In some embodiments, the conductive layer 1702 is not patterned in the BLC region 184. Thus, the bias pad layer 174 extends from the pixel array region 182, through the BLC region 184, and into the bonding pad region 186.

FIG. 21B illustrates a cross-sectional view 2120 of an image sensor device during intermediate stages of manufacturing operations corresponding to operation 218, in accordance with some embodiments. As shown in FIG. 21B, a low-n material layer 2106′ is formed over the isolation grid structure 120 and the light transmission layer 134. In some embodiments, the low-n material layer 2106′ is a transparent material with a refractive index less than a refractive index of the color filters 1930a-c. In some embodiments, the low-n material layer 2106′ is a dielectric, such as an oxide (e.g., SiO2) or hafnium oxide (e.g., HfO2), or a material with a refractive index less than silicon. In some embodiments, the low-n material layer 2106′ includes material that is different than the material of the light transmission layer 134. The low-n material layer 2106′ may be formed by a variety of techniques, such as CVD, PVD, atomic layer deposition (ALD), plasma-enhanced chemical vapor deposition (PECVD), atmospheric pressure chemical vapor deposition (APCVD), low-pressure CVD (LPCVD), high density plasma CVD (HDPCVD), atomic layer CVD (ALCVD), sub-atmospheric CVD (SACVD), and/or other suitable operations. In some embodiments, the low-n material layer 2106′ has a thickness in a range from about 1000 Å to about 3000 Å.

FIG. 21C illustrates a cross-sectional view 2130 of an image sensor device during intermediate stages of manufacturing operations also corresponding to operation 218, in accordance with some embodiments. Referring to FIG. 21B and FIG. 21C, subsequently, a photolithography operation is performed, wherein the low-n material layer 2106′ is patterned by a masking layer 2108 to form a low-n grid section 2106 of the upper grid structure 2110. Specifically, the low-n material layer 2106′ is patterned into the low-n grid section 2106 having low-n grid segments 2106a, 2106b. Due to the low refractive index of the low-n grid section 2106, the upper grid structure 2110 serves as a light guide to direct light to the color filters 1930a-c and to effectively increase the size of the color filters 1930a-c. Further, due to the low refractive index, the low-n grid section 2106 serves to provide optical isolation between neighboring image-sensing elements 112a-c. Light within the color filters 1930a-c that strikes the boundary with the low-n grid section 2106 typically undergoes total internal reflection due to the refractive indexes. The masking layer 2108 is subsequently removed.

FIG. 21D illustrates a cross-sectional view 2140 of an image sensor device during intermediate stages of manufacturing operations corresponding to operation 220, in accordance with some embodiments. At operation 220, a bonding pad structure, for example, the conductive bonding pad structure 150, may be exposed. As shown in cross-sectional view 2140 of FIG. 21D, an eighth etching process is performed on the dielectric fill material 154 to expose the conductive bonding pad structure 150. The eighth etching process may be performed using a patterned mask layer as previously discussed herein. The eighth etching process is performed by exposing the dielectric fill material 154 to one or more etchants with a patterned masking layer in place. The one or more etchants remove a portion of the dielectric fill material 154 in the bonding pad region 186 to define a fifth opening 2144. The fifth opening 2144 extends from the top surface 155 of the dielectric fill material 154 to the conductive bonding pad structure 150. The fifth opening 2144 is defined by sidewalls 2144s and a bottom surface 2144b. In some embodiments, as shown in FIG. 21D, the sidewalls 2144s of the fifth opening 2144 are defined by the dielectric fill material 154. In some embodiments, as shown in FIG. 21D, the bottom surface 2144b of the fifth opening 2144 is defined by the conductive bonding pad structure 150. In some embodiments, the fourth opening 2044 has a width in a range from about 0.3 μm to about 5 μm.

Still referring to FIG. 21D, FIG. 21D also illustrates an image sensor device during intermediate stages of manufacturing operations corresponding to operation 222 and operation 224, in accordance with some embodiments. At operation 222, a color filter layer 1930 may be formed over the upper grid structure 2110 in the pixel array region 182. In some embodiments, as shown in FIG. 20C, color filters 1930a-c are formed in openings 2128a-c which are defined by the upper grid structure 2110. At operation 224, the array of micro-lenses 1940a-c may be formed over the color filter layer 1930 and aligned with respective color filters 1930a-c and respective light detection regions 102a-c. In some embodiments, after forming the micro-lenses 1940a-c, the image sensor device may undergo further processing such as, for example, packaging.

According to an embodiment, an image sensor device is provided. The image sensor device comprises a device substrate having a frontside and a backside opposite the frontside; a plurality of image-sensing elements arranged within the device substrate; a light transmission layer formed over the plurality of image-sensing elements, wherein the light transmission layer comprises a backside, a frontside opposite the backside, the frontside of the light transmission layer adjacent to the backside of the device substrate; a light blocking grid overlying the device substrate and made up of a plurality of metal grid segments that surround outer perimeters of the plurality of image-sensing elements, wherein the plurality of metal grid segments overlie the plurality of image-sensing elements; and an isolation grid structure extending into the device substrate and made up of a plurality of isolation grid segments that surround the outer perimeters of the plurality of image-sensing elements, wherein the isolation grid structure comprises a passivation liner; and a conductive layer in contact with the passivation liner.

According to another embodiment, an image sensor device is provided. The image sensor device comprises a pixel array region, comprising: a device substrate having a frontside and a backside opposite the frontside; a plurality of image-sensing elements arranged within the device substrate; and an isolation grid structure extending into the device substrate and made up of a plurality of isolation grid segments that surround the outer perimeters of the plurality of image-sensing elements, wherein the isolation grid structure comprises an-indium-tin-oxide material; a black level correction (BLC) region adjacent to the pixel array region; a bonding pad region adjacent to the BLC region, comprising: a conductive bonding pad arranged within the device substrate; and a bias pad layer extending from the conductive bonding pad, through the BLC region, and contacting the isolation grid structure, wherein the bias pad layer electrically couples the conductive bonding pad with the isolation grid structure.

According to yet another embodiment, a method of manufacturing an image sensor device is provided. The method includes receiving a device substrate, the device substrate having a frontside and a backside opposite the frontside, and a plurality of image-sensing elements arranged within the device substrate; forming an isolation grid structure extending into the device substrate from the backside and made up of a plurality of isolation grid segments that surround outer perimeters of the plurality of image-sensing elements, wherein forming the isolation grid structure comprises: forming a trench in the device substrate; depositing a passivation liner along surfaces of the trench; and depositing an indium-tin-oxide (ITO) fill material on the passivation liner; forming a conductive layer over the backside of the device substrate; and patterning the conductive layer to form a light blocking grid over the isolation grid structure and a bias pad layer, wherein the bias pad layer extends from a conductive bonding pad formed in the device substrate to the isolation grid structure, the bias pad layer electrically couples the conductive bonding pad with the isolation grid structure, and the light blocking grid is made up of a plurality of metal grid segments that surround outer perimeters of the plurality of image-sensing elements, wherein the plurality of metal grid segments overlie the plurality of image-sensing elements.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An image sensor device, comprising:
a device substrate having a frontside and a backside opposite the frontside;
a plurality of image-sensing elements arranged within the device substrate;
a light transmission layer formed over the plurality of image-sensing elements, wherein the light transmission layer comprises a backside, a frontside opposite the backside, the frontside of the light transmission layer adjacent to the backside of the device substrate;
a light blocking grid overlying the device substrate and made up of a plurality of metal grid segments that surround outer perimeters of the plurality of image-sensing elements, wherein the plurality of metal grid segments overlie the plurality of image-sensing elements; and
an isolation grid structure extending into the device substrate and made up of a plurality of isolation grid segments that surround the outer perimeters of the plurality of image-sensing elements, wherein the isolation grid structure comprises:
a passivation liner; and
a conductive layer in contact with the passivation liner.

2. The image sensor device of claim 1, wherein the conductive layer comprises an ITO (indium tin oxide) material.

3. The image sensor device of claim 2, wherein a top surface of the ITO material, a top surface of the passivation liner, and the backside of the light transmission layer are substantially co-planar.

4. The image sensor device of claim 2, wherein the ITO material and the passivation liner extend above the backside of the device substrate.

5. The image sensor device of claim 1, further comprising:
a plurality of topographical features formed in the backside of the device substrate, wherein the topographical features comprise a plurality of recesses arranged between a plurality of protrusions the plurality of recesses and the plurality of protrusions separated by interior surfaces of the device substrate; and
a passivation layer formed over the backside of the device substrate in between the plurality of topographical features and the light transmission layer.

6. The image sensor device of claim 5, wherein the light transmission layer fills the plurality of recesses defined by interior surfaces of the device substrate and the light transmission layer extends above the backside of the device substrate.

7. The image sensor device of claim 1, further comprising:
an oxide material filling a plurality of first openings defined by the light blocking grid;
a plurality of color filters formed over the oxide material, wherein each color filter is formed over a corresponding image-sensing element; and
an array of micro-lenses formed over the plurality of color filters with each micro-lens of the array of micro-lenses aligned with a color filter, wherein a bottom surface of the light blocking grid contacts a top surface of the isolation grid structure.

8. The image sensor device of claim 1, further comprising:
a color filter layer formed in a plurality of first openings defined by the light blocking grid; and
an array of micro-lenses formed over the color filter layer, wherein a bottom surface of the light blocking grid contacts a top surface of the isolation grid structure.

9. An image sensor device, comprising:
a pixel array region, comprising:
a device substrate having a frontside and a backside opposite the frontside;
a plurality of image-sensing elements arranged within the device substrate; and
an isolation grid structure extending into the device substrate and made up of a plurality of isolation grid segments that surround the outer perimeters of the plurality of image-sensing elements, wherein the isolation grid structure comprises an-indium-tin-oxide material;
a black level correction (BLC) region adjacent to the pixel array region;
a bonding pad region adjacent to the BLC region, comprising:
a conductive bonding pad arranged within the device substrate; and
a bias pad layer extending from the conductive bonding pad, through the BLC region, and contacting the isolation grid structure, wherein the bias pad layer electrically couples the conductive bonding pad with the isolation grid structure.

10. The image sensor device of claim 9, further comprising:
a light blocking grid overlying the device substrate and surrounding outer perimeters of the plurality of image-sensing elements, such that a plurality of first openings defined by the plurality of metal grid segments overlie the plurality of image-sensing elements, wherein the bias pad layer and the light blocking grid comprise the same metal material.

11. The image sensor device of claim 9, wherein the bias pad layer contacts a buffer oxide layer and a dielectric fill material in the bonding pad region.

12. The image sensor device of claim 9, wherein the isolation grid structure further comprises a passivation liner and wherein a top surface of the ITO material and a top surface of the passivation liner are substantially co-planar.

13. The image sensor device of claim 9, wherein the isolation grid structure further comprises a passivation liner, and the ITO material is in contact with the passivation liner.

14. The image sensor device of claim 10, further comprising:
an oxide material filling the plurality of first openings defined by the light blocking grid;
a plurality of color filters formed over the oxide material, wherein each color filter is formed over a corresponding image-sensing element; and
an array of micro-lenses formed over the plurality of color filters with each micro-lens of the array of micro-lenses aligned with a color filter, wherein a bottom surface of the light blocking grid contacts a top surface of the isolation grid structure.

15. The image sensor device of claim 10, further comprising:
a color filter layer formed in the plurality of first openings defined by the light blocking grid; and
an array of micro-lenses formed over the color filter layer, wherein a bottom surface of the light blocking grid contacts a top surface of the isolation grid structure.

16. A method of manufacturing an image sensor device, comprising:
receiving a device substrate, the device substrate having a frontside and a backside opposite the frontside, and a plurality of image-sensing elements arranged within the device substrate;
forming an isolation grid structure extending into the device substrate from the backside and made up of a plurality of isolation grid segments that surround outer perimeters of the plurality of image-sensing elements, wherein forming the isolation grid structure comprises:
forming a trench in the device substrate;
depositing a passivation liner along surfaces of the trench; and
depositing an indium-tin-oxide (ITO) fill material on the passivation liner;
forming a conductive layer over the backside of the device substrate; and
patterning the conductive layer to form a light blocking grid over the isolation grid structure and a bias pad layer, wherein the bias pad layer extends from a conductive bonding pad formed in the device substrate to the isolation grid structure, the bias pad layer electrically couples the conductive bonding pad with the isolation grid structure, and the light blocking grid is made up of a plurality of metal grid segments that surround outer perimeters of the plurality of image-sensing elements, wherein the plurality of metal grid segments overlie the plurality of image-sensing elements.

17. The method of claim 16, further comprising:
filling a plurality of first openings with an oxide material;
forming a plurality of color filters over the oxide material, wherein each color filter is formed over a corresponding image-sensing element; and
forming an array of micro-lenses over the plurality of color filters with each micro-lens of the array of micro-lenses aligned with a color filter.

18. The method of claim 16, further comprising:
forming color filters in a plurality of first openings, wherein each color filter is formed over a corresponding image-sensing element; and
forming a plurality of micro-lenses over the color filters with each micro-lens is aligned with a color filter.

19. The method of claim 16, wherein a bottom surface of the light blocking grid contacts a top surface of the isolation grid structure.

20. The method of claim 16, further comprising exposing the backside of the device substrate to an etching process to form a plurality of topographical features in the backside of the device substrate prior to forming the isolation grid structure.
